(19) United States
(12) Patent Application Publication
(10) Pub. No.: US 2025/0294900 A1
(43) Pub. Date: Sep. 18, 2025

(54) SEMICONDUCTOR DEVICE, IMAGE SENSOR, AND LAYOUT DESIGN METHOD

(71) Applicant: SAMSUNG ELECTRONICS CO., LTD., Suwon-si (KR)

(72) Inventors: Chanmin PARK, Suwon-si (KR); Sangwoo Kim, Suwon-si (KR)

(73) Assignee: SAMSUNG ELECTRONICS CO., LTD., Suwon-si (KR)

(21) Appl. No.: 19/005,561

(22) Filed: Dec. 30, 2024

(30) Foreign Application Priority Data
Mar. 14, 2024 (KR) 10-2024-0036068

(51) Int. Cl. H10F 39/00; H10F 39/18

(52) U.S. Cl. CPC H10F 39/8023; H10F 39/182; H10F 39/811

(57) ABSTRACT

A semiconductor device, including: a first substrate; a first device isolation portion in the first substrate around a first active region extending in a first direction; a plurality of sub-transistors connected to form a logic transistor; and a common node region at a center of the first active region, wherein the common node region is shared by the plurality of sub-transistors, wherein each sub-transistor includes: at least three gate electrodes which cross the first active region in a second direction intersecting the first direction; and a plurality of source regions and a plurality of drain regions disposed in the first active region adjacent to sidewalls of the at least three gate electrodes, wherein the plurality of source regions are alternatingly arranged with the plurality of drain regions in the first direction.

### CROSS-REFERENCE TO RELATED APPLICATIONS

This application is based on and claims priority under 35 U.S.C. § 119 to Korean Patent Application No. 10-2024-0036068, filed on Mar. 14, 2024, in the Korean Intellectual Property Office, the disclosure of which is incorporated by reference herein in its entirety.

### BACKGROUND OF THE INVENTION

### 1. Field

The present disclosure relates to a semiconductor device, an image sensor, and a layout design method.

### 2. Description of Related Art

Due to their small size, multifunctional capabilities, and relatively low cost, semiconductor devices are important elements in the electronics industry. Accordingly, there is an increasing demand for semiconductor devices with high integration density. To increase the integration density of a semiconductor device, it may be beneficial to reduce linewidths of patterns included in the semiconductor device.

An image sensor may be a semiconductor device configured to convert an optical image to electric signals. Types of image sensors may include a charge coupled device (CCD) type and a complementary metal-oxide-semiconductor (CMOS) type. A CMOS-type image sensor (CIS) may include a plurality of pixels that are two-dimensionally arranged. Each of the pixels may include a photodiode (PD), which may be used to convert incident light to an electric signal.

### SUMMARY

Provided is a semiconductor device with an increased integration density.

Also provided is an image sensor with an increased integration density.

Also provided is a layout design method capable of increasing an integration density of a semiconductor device and simplifying an interconnection structure in the semiconductor device.

Additional aspects will be set forth in part in the description which follows and, in part, will be apparent from the description, or may be learned by practice of the presented embodiments.

In accordance with an aspect of the disclosure, a semiconductor device includes: a first substrate; a first device isolation portion in the first substrate around a first active region extending in a first direction; a plurality of sub-transistors disposed adjacently in the first direction on the first active region, wherein the plurality of sub-transistors are connected to form a logic transistor; and a common node region in the first active region, wherein the common node region is shared by the plurality of sub-transistors and positioned at a center of the first active region, wherein each sub-transistor of the plurality of sub-transistors includes: at least three gate electrodes which cross the first active region in a second direction and which are spaced apart in the first direction, wherein the second direction intersects the first direction; and a plurality of source regions and a plurality of drain regions disposed in the first active region adjacent to sidewalls of the at least three gate electrodes, wherein the plurality of source regions are alternatingly arranged with the plurality of drain regions in the first direction.

In accordance with an aspect of the disclosure, an image sensor includes: a first substrate including an analog-to-digital converter (ADC) circuit region including a plurality of ADC column regions; a device isolation portion in the first substrate around a plurality of active regions in each of the plurality of ADC column regions; a plurality of logic transistors in the plurality of active regions; a plurality of interconnection lines connecting the plurality of logic transistors; a first interlayer insulating layer on the plurality of logic transistors, the plurality of interconnection lines, and the first substrate; a second interlayer insulating layer on the first interlayer insulating layer; a second substrate on the second interlayer insulating layer, wherein the second substrate includes a plurality of photoelectric conversion regions; a deep isolation portion in the second substrate, wherein the deep isolation portion separates the plurality of photoelectric conversion regions; and a color filter array and a micro lens array sequentially stacked on the second substrate, wherein the plurality of ADC column regions is arranged in a first direction, wherein each ADC column region of the plurality of ADC column regions and each active region of the plurality of active regions extends in a second direction intersecting the first direction, wherein, in the each ADC column region, the plurality of active regions is arranged in the second direction to form a column, wherein each logic transistor of the plurality of logic transistors includes M sub-transistors disposed in the second direction on a corresponding active region from among the plurality of active regions, where M is an integer greater than or equal to two (“2”), wherein the each sub-transistor includes N unit transistors disposed in the second direction, where N is an integer greater than or equal to three (“3”), wherein each unit transistor of the N unit transistors includes a gate electrode, and a source region and a drain region adjacent to the gate electrode, wherein at least one of the source region and the drain region between adjacent unit transistors is shared by the adjacent unit transistors, and wherein a common node region is disposed in the corresponding active region to connect the M sub-transistors.

In accordance with an aspect of the disclosure, a semiconductor device includes: a first substrate; a first device isolation portion in the first substrate around a first active region that extending in a first direction; a plurality of sub-transistors disposed in the first direction on the first active region, wherein the plurality of sub-transistors connected to form a logic transistor; a common node region in the first active region between the plurality of sub-transistors, wherein the common node region is shared by the plurality of sub-transistors; and a first contact plug and a second contact plug on the common node region, wherein the first contact plug is spaced apart from the second contact plug in a second direction intersecting the first direction.

In accordance with an aspect of the disclosure, a layout design method includes: dividing a logic transistor having a first gate width and a first gate length into a plurality of unit transistors, which are arranged to form M rows and N columns, where M is an integer greater than or equal to two (“2”) and N is an integer greater than or equal to three (“3”), wherein each unit transistor of the plurality of unit transistors has a second gate length and a second gate width, wherein the first gate length is M times the second gate length, wherein the first gate width is N times the second gate width, and wherein in each row of the M rows, N unit transistors are connected in parallel to form a sub-transistor and M sub-transistors are connected in series to form the logic transistor; arranging the plurality of unit transistors in a first direction on an active region extending in the first direction, wherein a width of the active region in a second direction crossing the first direction is equal to the second gate width, wherein the each unit transistor includes a gate electrode and a source region and a drain region adjacent to the gate electrode, wherein the plurality of unit transistors are mirror-symmetric in the first direction, wherein the gate electrode crosses the active region in the second direction, wherein at least one of the source region and the drain region between adjacent unit transistors is shared by the adjacent unit transistors, and a wherein common node region is between the M sub-transistors; forming a gate connection line to connect the gate electrode of the each unit transistor in the first direction; forming source connection lines to connect some source regions included in the M sub-transistors in the first direction; forming drain connection lines to connect some drain regions included in the M sub-transistors in the first direction; and forming common node lines to connect the common node region to remaining source regions or remaining drain regions included in the M sub-transistors, wherein the source connection lines and the drain connection lines or the common node lines are arranged along a first straight line where the drain connection lines or the common node lines are located, wherein the drain connection lines and the common node lines are arranged along a second straight line, and wherein the first straight line is spaced apart from the second straight line in the second direction.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a diagram illustrating a layout design method according to an embodiment;

FIGS. 2A and 2B are diagrams illustrating a layout design method according to an embodiment;

FIGS. 3A and 3B are diagrams illustrating a layout design method according to an embodiment;

FIG. 4 is a diagram illustrating a layout design method according to an embodiment;

FIGS. 5A and 5B are layouts illustrating a logic transistor according to an embodiment;

FIGS. 6A to 6D are circuit diagrams illustrating the logic transistor of FIG. 5A or 5B, according to embodiments;

FIG. 7 is a perspective view illustrating a logic transistor with the layout of FIG. 5A, according to embodiments;

FIGS. 8A and 8B are layouts illustrating a logic transistor according to an embodiment;

FIGS. 9A and 9B are layouts of a sub-transistor, which includes four unit transistors according to an embodiment;

FIG. 9C is a circuit diagram of the sub-transistor of FIG. 9A or 9B according to an embodiment;

FIGS. 10A and 10B are layouts illustrating a logic transistor according to an embodiment;

FIGS. 10C to 10F are circuit diagrams of the logic transistor of FIG. 10A or 10B, according to an embodiment;

FIGS. 11A and 11B are layouts illustrating a logic transistor according to an embodiment;

FIG. 12 is a circuit diagram of the logic transistor of FIG. 11A or 11B, according to an embodiment;

FIG. 13 is a layout of a sub-transistor including five unit transistors according to an embodiment;

FIG. 14 is a layout illustrating a logic transistor according to an embodiment;

FIG. 15 is a layout of a sub-transistor including eight unit transistors according to an embodiment;

FIG. 16 is a block diagram illustrating an image sensor according to an embodiment;

FIG. 17 is a circuit diagram illustrating an active pixel sensor array of an image sensor according to an embodiment;

FIG. 18 is a sectional view illustrating an image sensor according to an embodiment;

FIG. 19 is a plan view schematically illustrating an ADC circuit region according to an embodiment;

FIG. 20A illustrates a portion of an ADC circuit, according to an embodiment;

FIG. 20B is a detailed circuit diagram of a comparator of FIG. 20A, according to an embodiment;

FIG. 21 is a schematic plan view of an ADC column region, according to an embodiment;

FIG. 22 is a sectional view illustrating an image sensor according to an embodiment;

### DETAILED DESCRIPTION

Example embodiments are described below with reference to the accompanying drawings, in which some example embodiments are shown. In the present disclosure, the term ‘source region’ may be referred to as ‘source node’, ‘first impurity region’, ‘first doped region’, ‘first node’, or ‘first node region’. The term ‘drain region’ may be referred to as ‘drain node’, ‘second impurity region’, ‘second doped region’, ‘second node’ or ‘second node region’. In the present disclosure, terms such as first, second, etc., indicating order, may be used to distinguish elements that perform the same or similar functions from one another, and their numbering can change according to the mentioned order.

Because of increasing demand for scaled semiconductor fabrication processes, it may be desirable to reduce a size of geometric features (e.g., a gate width and/or a gate length) of a gate electrode of a transistor. For some circuits, in order to achieve desired characteristics in noise and size matching, a minimum feature size of the gate electrode of the transistor may be maintained within a range larger than a specific value. Accordingly, embodiments may provide a method of connecting several unit transistors, which have a limited size, to form a single logic transistor.

In the case where the several unit transistors are provided, a complex interconnection structure may be used to connect the unit transistors to each other, and an area for the interconnection structure may be increased. This may lead to a difficulty in increasing an integration density of the semiconductor device. However, according to an embodiment, a layout design method may be provided to form the unit transistors in a manner of meeting the increasing demand for scaled-down semiconductor fabrication processes and to reduce an area occupied by the interconnection structure of the logic transistor.

In the present disclosure, the term ‘logic transistor’ may refer to a transistor, which may be provided as a part of a logic circuit for driving transfer transistors and pixel transistors (e.g., a reset transistor, a selection transistor, a source follower transistor, a dual conversion transistor, and so forth) in a pixel array of an image sensor. However, in an embodiment, it may refer to a transistor, which is provided as a part of a logic circuit for driving memory cell transistors in a memory cell array of a memory device.

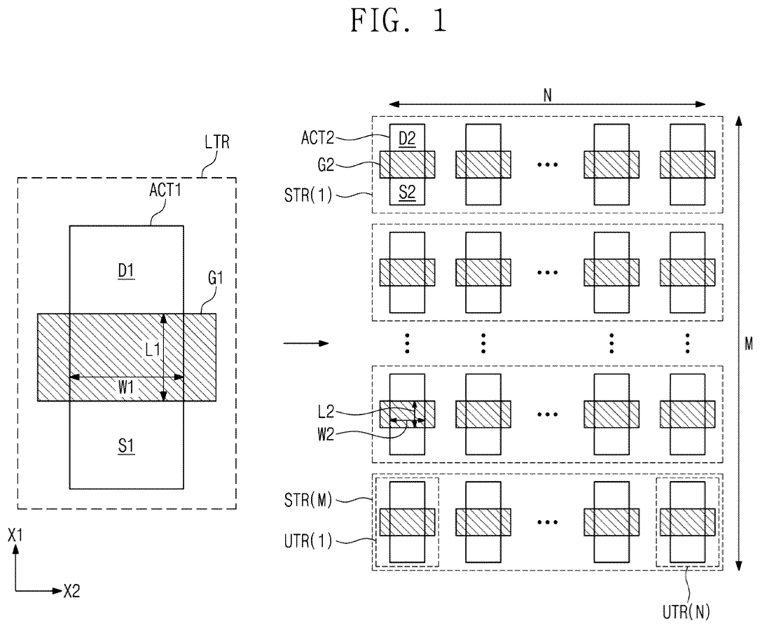

FIG. 1 is a diagram illustrating a layout design method according to an embodiment from a layout perspective.

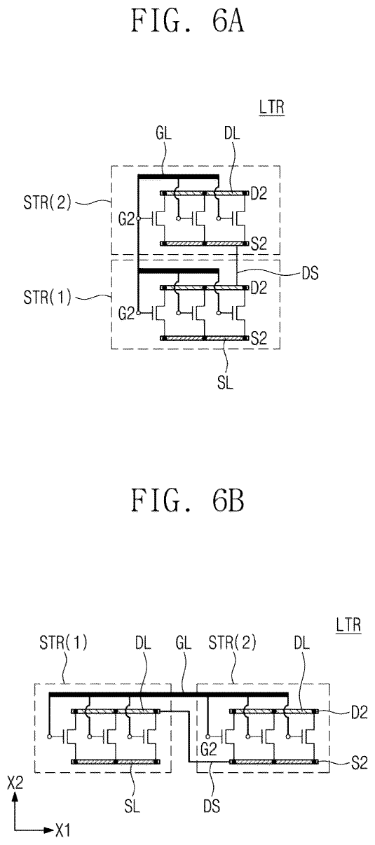

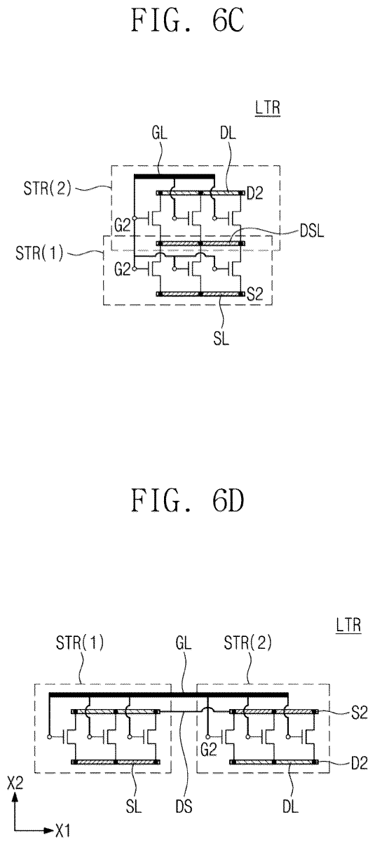

Referring to FIG. 1, the layout design method may include choosing a logic transistor LTR to be designed. The logic transistor LTR may be disposed on a first active region ACT1, which may be confined within a substrate. The logic transistor LTR may include a first gate electrode G1 and may further include a first source region S1 and a first drain region D1, which may be disposed in the substrate and at both sides of first gate electrode G1. The first source region S1 and the first drain region D1 may be spaced apart from each other in a first direction X1. The first gate electrode G1 may cross the first active region ACT1 in a second direction X2. A gate insulating layer Gox (as shown for example in FIG. 6) may be interposed between the first gate electrode G1 and the substrate. The logic transistor LTR may have a first gate length L1 and a first gate width W1. The first gate length L1 may correspond to a length of the first gate electrode G1, which may be overlapped with the first active region ACT1 in the first direction X1. The first gate width W1 may correspond to a width of the first gate electrode G1, which may be overlapped with the first active region ACT1 in the second direction X2. If the first gate length L1 and the first gate width W1 are set within ranges which may be used to obtain an output signal having a desired level from the logic transistor LTR, there may be difficulties in achieving a scaled-down semiconductor fabrication process or reducing a noise issue.

Therefore, in a layout design method according to an embodiment, in order to realize the logic transistor LTR, the logic transistor LTR may be divided into unit transistors UTR, which may be arranged to form M rows and N columns which may be connected to each other. Here, M may denote a natural number that is greater than or equal to two (“2”), and N may denote a natural number that is greater than or equal to three (“3”). For example, each of the unit transistors UTR may be disposed on a second active region ACT2. Each of the unit transistors UTR may include a second gate electrode G2 and a second source region S2 and a second drain region D2, which may be disposed in the substrate and at both sides of the second gate electrode G2. The second source region S2 and the second drain region D2 may be spaced apart from each other in the first direction X1. The second gate electrode G2 may cross the second active region ACT2 in the second direction X2. A gate insulating layer Gox (as shown for example in FIG. 6) may be interposed between the second gate electrode G2 and the substrate. Each of the unit transistors UTR may have a second gate length L2 and a second gate width W2.

In the present disclosure, the second gate electrode G2 may be referred to as a ‘unit gate electrode’, the second source region S2 may be referred to as a ‘unit source region’, and the second drain region D2 may be referred to as a ‘unit drain region’. The second gate length L2 may be referred to as a ‘unit gate length’. The second gate width W2 may be referred to as a ‘unit gate width’.

The second gate length L2 may correspond to a length of the second gate electrode G2, which may be overlapped with the second active region ACT2 in the first direction X1. The second gate width W2 may correspond to a width of the second gate electrode G2, which may be overlapped with the second active region ACT2 in the second direction X2. The second gate length L2 and the second gate width W2 may be realized through a scaled-down semiconductor fabrication process. For example, M times the second gate length L2 may correspond to the first gate length L1, and N times the second gate width W2 may correspond to the first gate width W1.

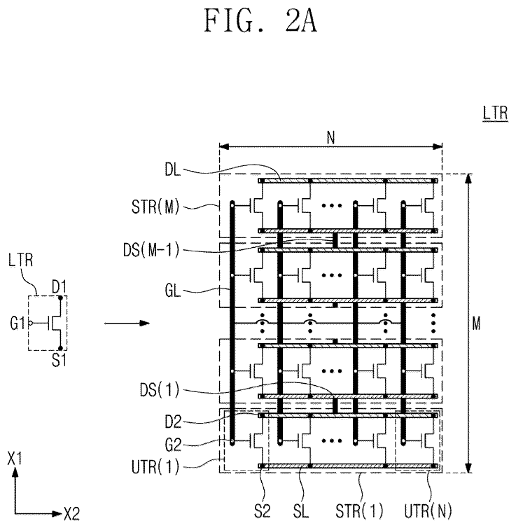

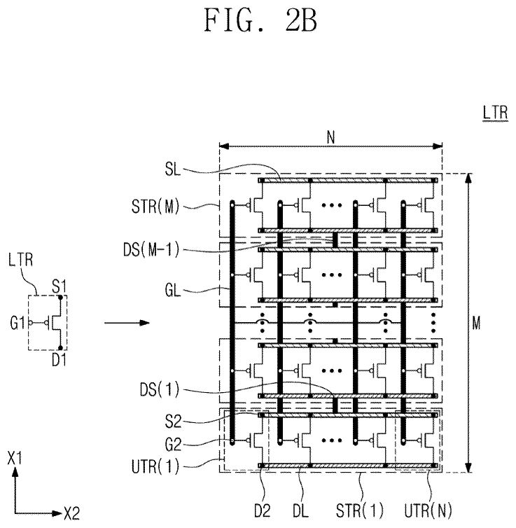

The change in the layout of FIG. 1 may be depicted through the circuit diagrams of FIGS. 2A and 2B.

FIGS. 2A and 2B are diagrams illustrating a layout design method according to an embodiment from a circuitry perspective. FIG. 2A depicts an n-type field effect transistor (FET) or an n-type metal-oxide-semiconductor field-effect transistor (NMOSFET), and FIG. 2B depicts a p-type FET or PMOSFET.

Referring to FIGS. 1, 2A, and 2B, N unit transistors UTR (e.g., transistor UTR(1) through transistor UTR(N)) may be arranged in the second direction X2 to form one row, and may be connected in parallel to form a single sub-transistor STR. In embodiments, M sub-transistors STR (e.g., sub-transistor STR(1) through sub-transistor STR(M)) may be arranged in the first direction X1 to form one column and may be connected in series to form the logic transistor LTR. The second gate electrodes G2 of the unit transistors UTR may be electrically connected to each other via a gate connection line GL. Within each sub-transistor STR, the second source regions S2 of the unit transistors UTR included in the sub-transistor STR may be connected to each other by a source connection line SL. Within each sub-transistor STR, the second drain regions D2 of the unit transistors UTR included in the sub-transistor STR may be connected to each other by a drain connection line DL. A common node region DS may connect adjacent sub-transistors STR to each other. For example, the drain connection line DL in one of the sub-transistors STR may be connected to the source connection line SL in an adjacent sub-transistor STR in the first direction X1, by the common node region DS. In the examples shown in FIGS. 2A and 2B, (M−1) common node regions DS may be provided. The common node region DS may include, for example a first common node regions DS(1) through an (M−1)th common node region DS(M−1).

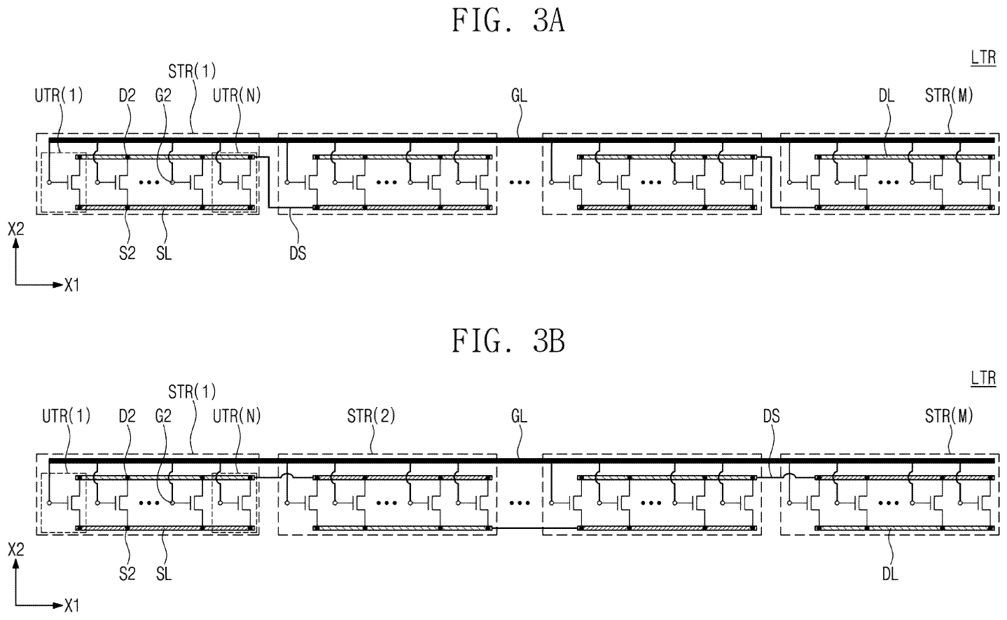

FIGS. 3A and 3B are diagrams illustrating a layout design method according to an embodiment from a circuitry perspective.

Referring to FIG. 3A, in the layout design method, unit transistors UTR included in each sub-transistor STR may be arranged to form a line in the first direction X1. The sub-transistors STR may be arranged to form a line in the first direction X1, as shown in FIG. 3A. Interconnection lines may be disposed to connect the sub-transistors STR to form the logic transistors LTR.

In the matrix arrangement of the unit transistors UTR shown in FIGS. 2A and 2B, a first row of the unit transistors UTR parallel to a horizontal direction X2 may be arranged in the first direction X1, a next row of the unit transistors UTR parallel to a horizontal direction X2 may be arranged in the first direction X1, and this process may be sequentially repeated until an M-th row of the unit transistors UTR is disposed. For example, the unit transistors UTR may be placed in a ‘Z’-shaped order, in the matrix arrangement shown in FIGS. 2A and 2B, to form the arrangement of FIGS. 3A and 3B.

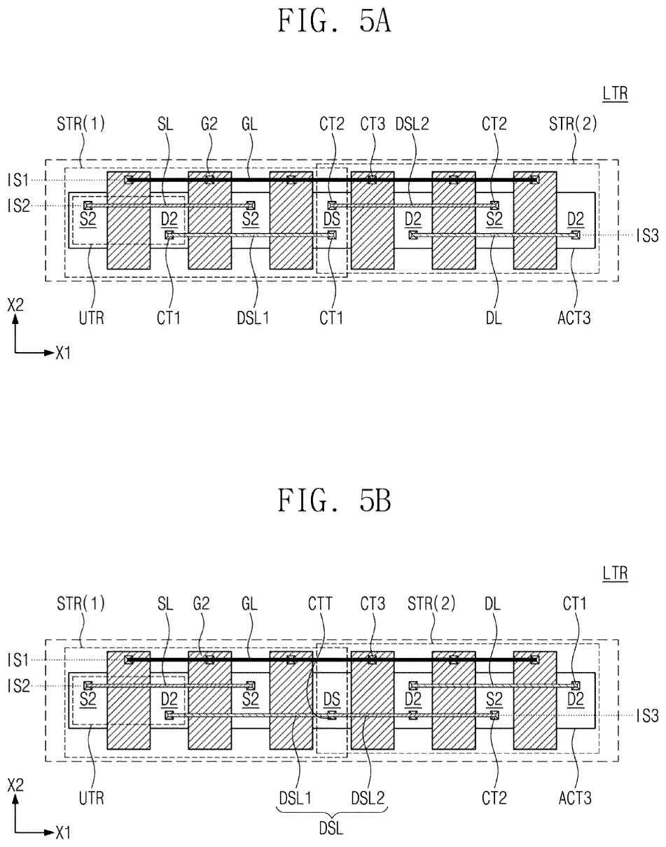

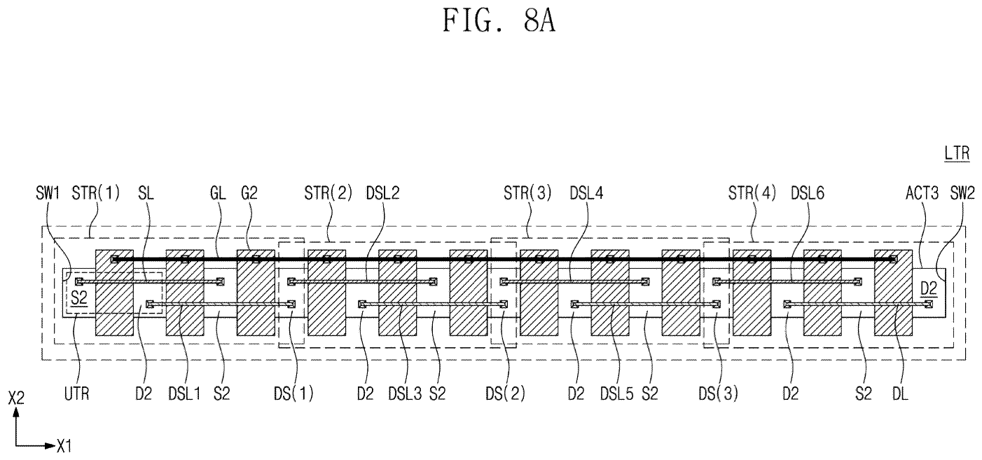

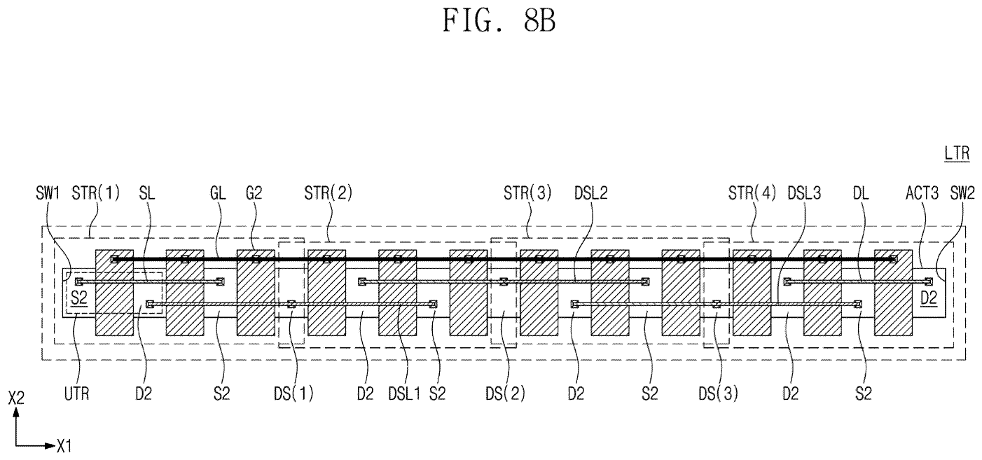

Referring to FIG. 3A, the second gate electrodes G2 of all of the unit transistors UTR included in the logic transistor LTR may be connected to each other by the gate connection line GL. The gate connection line GL may extend in the first direction X1. Within each sub-transistor STR, the second source regions S2 of the unit transistors UTR included in the sub-transistor STR may be connected to each other by the source connection line SL. Within each sub-transistor STR, the second drain regions D2 of the unit transistors UTR included in the sub-transistor STR may be connected to each other by the drain connection line DL. The common node region DS may connect the sub-transistors STR, which are adjacent to each other. For example, the drain connection line DL in one of the sub-transistors STR may be connected to the source connection line SL in an adjacent sub-transistor STR in the first direction X1, by the common node region DS. In the example shown in FIG. 3A, the source connection lines SL may be arranged along a straight line parallel to the first direction X1. The drain connection lines DL may be arranged along another straight line parallel to the first direction X1. The source connection line SL, the drain connection line DL, and the gate connection line GL may be spaced apart from each other in the second direction X2. The arrangement of FIG. 3A may be applied to a layout design method described below with reference to FIG. 5A and FIG. 8A.

As shown in FIG. 3B, even-numbered ones of the sub-transistors STR may be provided to be symmetric with respect to odd-numbered ones of the sub-transistors STR in the second direction X2. For example, the source connection line SL in the odd-numbered ones of the sub-transistors STR and the drain connection line DL in the even-numbered ones of the sub-transistors STR may be arranged along a first straight line. According to embodiments, when one or more elements are described as being “arranged along” a straight line, this may mean that the one or more elements are located on or disposed according to a straight line, which may be for example an imaginary or hypothetical line. The source connection line SL in the even-numbered ones of the sub-transistors STR and the drain connection line DL in the odd-numbered ones of the sub-transistors STR may be arranged along a second straight line which is different from the first straight line. The common node region DS may be provided to have a zigzag shape. The arrangement of FIG. 3B may be applied to a layout design method described below with reference to FIG. 5B and FIG. 8B.

In the case where the arrangement of the unit transistors UTR of FIG. 2A or 2B is changed to the arrangement of FIG. 3A or 3B, it may be possible to reduce the number of the connection nodes and to place the gate connection line GL, the source connection line SL, the drain connection line DL along three straight lines. This may make it possible to reduce the complexity and difficulty in placing the gate connection line GL, the source connection line SL, the drain connection line DL, which may be used to connect the unit transistors UTR to each other.

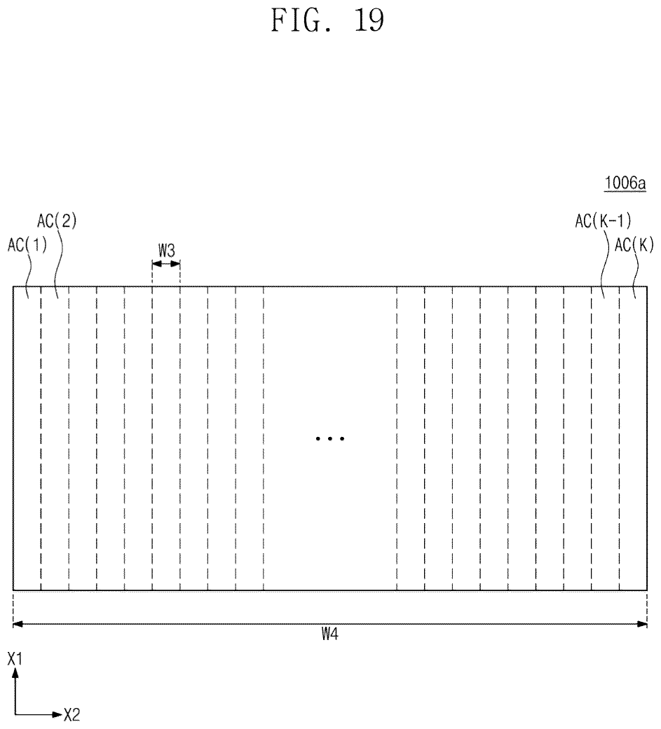

In addition, it may be possible to reduce an area that is occupied by the gate connection line GL, the source connection line SL, and the drain connection line DL and to reduce a width (e.g., a third width W3 shown in FIG. 19), in the second direction X2, of a region for the logic transistor LTR. Accordingly, it may be possible to realize a semiconductor device with an increased integration density.

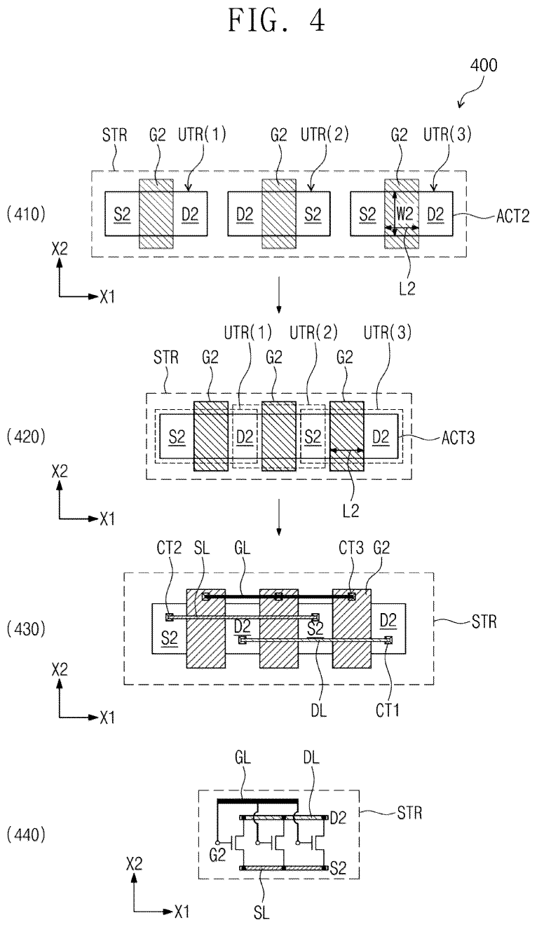

FIG. 4 is a diagram illustrating a layout design method according to an embodiment.

FIG. 4 illustrates a process 400 of designing a layout of a sub-transistor STR, which includes three unit transistors UTR connected in parallel. For example, at operation 410, the first to third unit transistors UTR(1) to UTR(3) may be alternatingly placed to form one row in the first direction X1 and to have mirror symmetry with respect to each other. For example, in the first and third unit transistors UTR(1) and UTR(3), the second source region S2 may be located to the left of the second gate electrode G2, and the second drain region D2 may be located to the right of the second gate electrode G2. In the second unit transistor UTR(2), the second source region S2 may be located to the right of the second gate electrode G2, and the second drain region D2 may be located to the left of the second gate electrode G2.

At operation 420, the first to third unit transistors UTR(1) to UTR(3) may be connected such that they are overlapped with each other in the first direction X1. Here, the second drain region D2 of the second unit transistor UTR(2) may be overlapped with, or shared by, the second drain region D2 of the first unit transistor UTR(1). The second source region S2 of the second unit transistor UTR(2) may be overlapped with, or shared by, the second source region S2 of the third unit transistor UTR(3). The first to third unit transistors UTR(1) to UTR(3) included in the sub-transistor STR may be arranged in a finger type arrangement.

At operation 430, interconnection lines may be placed to connect the first to third unit transistors UTR(1) to UTR(3) to each other. First contact plugs CT1 may be disposed on the second drain regions D2, respectively. The drain connection line DL may connect the first contact plugs CT1 to each other. A second contact plug CT2 may be disposed on the second source regions S2. The source connection line SL may connect the second contact plugs CT2 to each other. A third contact plug CT3 may be disposed on the second gate electrodes G2. The gate connection line GL may connect the third contact plugs CT3. The source connection line SL, the drain connection line DL, and the gate connection line GL may extend the first direction X1 and may be spaced apart from each other in the second direction X2. At operation 430, the sub-transistor STR may have the same circuit structure as that shown at operation 440, at which the sub-transistor STR is completed.

FIGS. 5A and 5B are layouts illustrating a logic transistor according to an embodiment.

FIG. 5A illustrates a layout of the logic transistor LTR constructed by connecting two sub-transistors STR, each of which has the layout corresponding to operation 430 of FIG. 4, in the first direction X1. For example, the first and second sub-transistors STR(1) and STR(2) may be disposed side by side in the first direction X1 to form one logic transistor LTR. The logic transistor LTR may be disposed in a third active region ACT3. The third active region ACT3 may have a shape that is obtained by connecting two second active regions ACT2, which are provided to have the layout corresponding to operation 430 of FIG. 4, in the first direction X1. The third active region ACT3 may have a second width W2 in the second direction X2.

Each of the first and second sub-transistors STR(1) and STR(2) may have the layout corresponding to operation 430 of FIG. 4. Here, the layouts of the first and second sub-transistors STR(1) and STR(2) may be connected such that the rightmost second drain region D2 in the first sub-transistor STR(1) is in contact with, or overlapped with, the leftmost second source region S2 in the second sub-transistor STR(2).

An overlap region between the first and second sub-transistors STR(1) and STR(2) may serve as the common node region DS. The common node region DS may correspond to the rightmost second drain region D2 of the first sub-transistor STR(1) and may correspond to the leftmost second source region S2 of the second sub-transistor STR(2). The first and second sub-transistors STR(1) and STR(2) may share the common node region DS therebetween.

In the first sub-transistor STR(1), the drain connection line DL (as shown for example in FIG. 4, at operation 430) connecting the second drain regions D2 may serve as a first common node line DSL1 in FIGS. 5A and 5B. For example, the first common node line DSL1 may connect the second drain region D2 of the first sub-transistor STR(1) to the common node region DS.

In the second sub-transistor STR(2), the source connection line SL (as shown for example in FIG. 4, at operation 430) connecting the second source regions S2 may serve as a second common node line DSL2 in FIGS. 5A and 5B. For example, the second common node line DSL2 may connect the second source region S2 of the second sub-transistor STR(2) to the common node region DS.

The first contact plug CT1, which may be connected to the first common node line DSL1, and the second contact plug CT2, which may be connected to the second common node line DSL2, may be disposed on the common node region DS. The second contact plug CT2 may be spaced apart from the first contact plug CT1 in the second direction X2. The common node region DS may connect the first common node line DSL1 to the second common node line DSL2. As a result, it may be unnecessary to place an additional line connecting the first common node line DSL1 to the second common node line DSL2 and, thus, the layout may be simplified.

The second gate electrodes G2 of the first and second sub-transistors STR(1) and STR(2) may be connected to each other by the gate connection line GL extending in the first direction X1. The gate connection line GL may be arranged along a first straight line IS1. The source connection line SL of the first sub-transistor STR(1) and the second common node line DSL2 of the second sub-transistor STR(2) may be arranged along a second straight line IS2. The first common node line DSL1 of the first sub-transistor STR(1) and the drain connection line DL of the second sub-transistor STR(2) may be arranged along a third straight line IS3. The first to third straight lines IS1, IS2, and IS3 may be spaced apart from each other in the second direction X2.

During the operation of the logic transistor LTR of FIG. 5A, the same gate voltage may be simultaneously applied to the second gate electrodes G2. A source voltage may be applied to the source connection line SL of the first sub-transistor STR(1), and a drain voltage may be applied to the drain connection line DL of the second sub-transistor STR(2). The gate voltage, the source voltage, and the drain voltage may not be applied to the first and second common node lines DSL1 and DSL2. A voltage may be applied to the first and second common node lines DSL1 and DSL2 through the common node region DS.

In the layout of FIG. 5A, the drain connection line DL and the second common node line DSL2 of the second sub-transistor STR(2) may be placed to have mirror symmetry in the second direction X2. In this case, the layout of FIG. 5B may be formed. For example, referring to FIG. 5B, the first contact plug CT1 on the common node region DS in FIG. 5A may be merged with the second contact plug CT2 to form a common contact plug CTT. The first and second common node lines DSL1 and DSL2 on the common contact plug CTT may be connected to each other to form a common node line DSL. In the logic transistor LTR of FIG. 5B, the source connection line SL of the first sub-transistor STR(1) and the drain connection line DL of the second sub-transistor STR(2) may be arranged along the second straight line IS2. The common node line DSL may be arranged along the third straight line IS3. The gate voltage, the source voltage, and the drain voltage may not be applied to the common node line DSL. A voltage may be applied to the common node line DSL through the common node region DS. Other portions may have the same or similar structural features to those in the example shown in FIG. 5A.

FIGS. 6A to 6D are circuit diagrams illustrating the logic transistor of FIG. 5A or 5B.

The logic transistor LTR of FIG. 5A or 5B may be depicted by the circuit diagrams of FIGS. 6A to 6D. For example, the first and second sub-transistors STR(1) and STR(2) may be connected in series, and each of the sub-transistors STR(1) and STR(2) may include three unit transistors UTR that are connected in parallel. The logic transistor LTR of FIG. 5A may have a circuit structure similar to a circuit structure of FIG. 6A or 6B. The logic transistor LTR of FIG. 5B may have a circuit structure similar to a circuit structure of FIG. 6C or 6D.

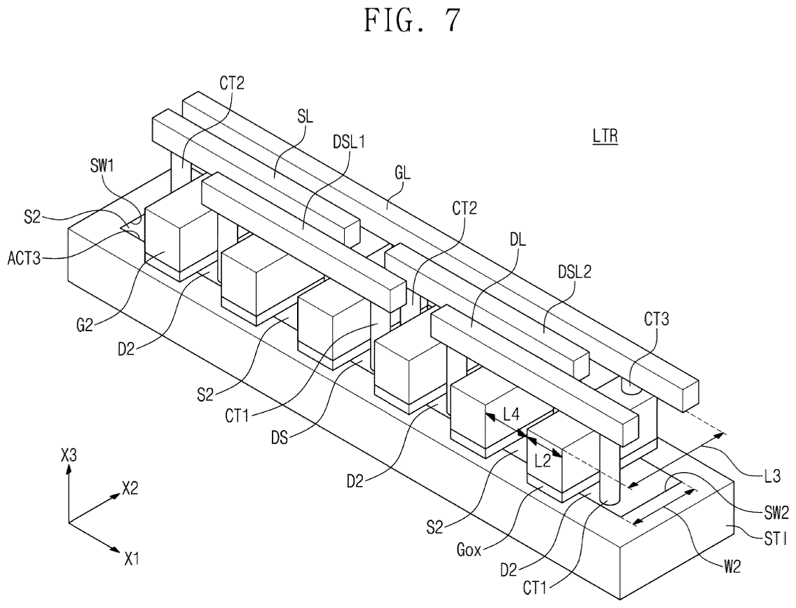

FIG. 7 is a perspective view illustrating a logic transistor with the layout of FIG. 5A.

Referring to FIG. 7, a device isolation portion STI may be disposed in a substrate 1 to confine the third active region ACT3. The substrate 1 may be a semiconductor substrate (e.g., a silicon wafer). The device isolation portion STI may be formed of or include an insulating material (e.g., silicon oxide, silicon nitride, or silicon oxynitride). The third active region ACT3 may have a shape that is elongated or extended in the first direction X1. The third active region ACT3 may have a first sidewall SW1 and a second sidewall SW2, which may be opposite to each other in the first direction X1. The third active region ACT3 may have a second width W2 in the second direction X2 that is not parallel to the first direction X1.

Six second gate electrodes G2, which may be arranged in a 2×3 shape, may be disposed on the third active region ACT3 to cross the third active region ACT3 in the second direction X2. The second gate electrodes G2 may be formed of or include at least one of doped polysilicon and/or metallic materials (e.g., tungsten and aluminum). Each of the second gate electrodes G2 may have a third length L3 in the second direction X2. The third length L3 may be larger than the second width W2 of the third active region ACT3. A gate insulating layer Gox may be interposed between the second gate electrodes G2 and the substrate 1. The gate insulating layer Gox may be formed of or include at least one of silicon oxide, silicon nitride, or metal oxide materials and may have a single-or multi-layered structure.

Seven impurity regions S2, D2, and DS may be disposed in the third active region ACT3 and near sidewalls of the second gate electrodes G2. The impurity regions S2, D2, and DS may be doped with n-type impurities (e.g., phosphorus or arsenic) or p-type impurities (e.g., boron). The impurity regions S2, D2, and DS may include the second source regions S2, the second drain regions D2, and the common node region DS. The second source and drain regions S2 and D2 may be alternatingly disposed in the first direction X1. The common node region DS may be disposed to be overlapped with the center of the third active region ACT3. The first contact plugs CT1 may be disposed on the second drain regions D2, respectively. The second contact plugs CT2 may be disposed on the second source regions S2, respectively. The third contact plugs CT3 may be disposed on the second gate electrodes G2, respectively. The first contact plug CT1 and the second contact plug CT2 may be disposed on the common node region DS.

The source connection line SL may connect the first and third ones of the second source regions S2 in the first direction X1 to each other. For example, the source connection line SL may connect first and third impurity regions S2 in an order moving away from the first sidewall SW1 of the third active region ACT3.

The drain connection line DL may connect first and second ones of the second drain regions D2 in the opposite of the first direction X1 (e.g., the negative direction X1) to each other. For example, the drain connection line DL may connect first and third impurity regions D2, which are located at the first and third in an order moving away from the second sidewall SW2 of the third active region ACT3.

The first common node line DSL1 may connect a first one of the second drain regions D2 in the first direction X1 to the common node region DS. For example, the first common node line DSL1 may connect the first impurity region D2 in an order moving away from the first sidewall SW1 of the third active region ACT3, to the impurity region DS.

The second common node line DSL2 may connect a first one of the second source regions S2 in the opposite of the first direction X1 to the common node region DS. For example, the second common node line DSL2 may connect the first impurity region S2 in an order moving away from the second sidewall SW2 of the third active region ACT3 to the impurity region DS.

The gate connection line GL may connect the third contact plugs CT3 to each other. The gate connection line GL, the source connection line SL, the drain connection line DL, the first common node line DSL1, and the second common node line DSL2 may cross the second gate electrodes G2 in the first direction X1 and may be overlapped with the third active region ACT3.

Each of the gate connection line GL, the source connection line SL, the drain connection line DL, the first common node line DSL1, the second common node line DSL2, and the first and second contact plugs CT1 and CT2 may be formed of or include at least one of metallic materials (e.g., titanium, tantalum, tungsten, aluminum, and copper).

FIGS. 8A and 8B are layouts illustrating a logic transistor according to an embodiment.

Each of the layouts of the logic transistors LTR illustrated in FIGS. 8A and 8B may be constructed by connecting four sub-transistors STR, each of which may be the layout corresponding to operation 430 of FIG. 4, in the first direction X1. For example, the first to fourth sub-transistors STR(1) to STR(4) may be arranged in the first direction X1 to form one logic transistor LTR. Each of the first to fourth sub-transistors STR(1) to STR(4) may have the layout in corresponding to operation 430 of FIG. 4. Here, the layouts of the first to fourth sub-transistors STR(1) to STR(4) may be connected such that edge impurity regions (e.g., S2 or D2) of the first to fourth sub-transistors STR(1) to STR(4) are in contact with each other. An overlap region between each adjacent pair of the first to fourth sub-transistors STR(1) to STR(4) may serve as the common node region DS. The sub-transistors STR(1) to STR(4) may be configured to share the common node region DS therebetween. In the examples shown in FIGS. 8A and 8B, the logic transistor LTR may include three common node regions DS(1) to DS(3).

The drain connection line DL corresponding to operation 430 of FIG. 4, which may be used to connect the second drain regions D2 to each other, may serve as the first common node line DSL1 in the first sub-transistor STR(1) of FIG. 8A. For example, the first common node line DSL1 may connect the second drain region D2 of the first sub-transistor STR(1) to the first common node region DS(1).

The second source region S2 of the first sub-transistor STR(1), which may be closest to the first sidewall SW1 of the third active region ACT3, may be connected to the source connection line SL. The second drain region D2 of the fourth sub-transistor STR(4), which may be closest to the second sidewall SW2 of the third active region ACT3, may be connected to the drain connection line DL.

In FIG. 8A, the second common node line DSL2 may connect the first common node region DS(1) to the second source region S2 of the second sub-transistor STR(2). A third common node line DSL3 may connect the second drain region D2 of the second sub-transistor STR(2) to the second common node region DS(2). A fourth common node line DSL4 may connect the second common node region DS(2) to the second source region S2 of the third sub-transistor STR(3). A fifth common node line DSL5 may connect the second drain region D2 of the third sub-transistor STR(3) to the third common node region DS(3). A sixth common node line DSL6 may connect the third common node region DS(3) to the second source region S2 of the fourth sub-transistor STR(4). The first to sixth common node lines DSL1 to DSL6 may be arranged in a zigzag shape (e.g., an alternating shape) to connect two adjacent ones of the impurity regions S2, D2, or DS to each other, as shown in FIG. 8A. Other portions may have the same or similar structural features to those in one of the embodiments described above.

As shown in FIG. 8B, the first common node line DSL1 may connect the second drain region D2 of the first sub-transistor STR(1), the first common node region DS(1), and the second source region S2 of the second sub-transistor STR(2) to each other. The second common node line DSL2 may connect the second drain region D2 of the second sub-transistor STR(2), the second common node region DS(2), and the second source region S2 of the third sub-transistor STR(3) to each other. The third common node line DSL3 may connect the second drain region D2 of the third sub-transistor STR(3), the third common node region DS(3), and the second source region S2 of the fourth sub-transistor STR(4) to each other. The first to third common node lines DSL1 to DSL3 may be arranged in a zigzag shape to connect three impurity regions S2, D2, or DS, which may be spaced apart from each other, as shown in FIG. 8B.

In the case where the sub-transistor STR includes three or more odd-numbered unit transistors UTR, the interconnection and arrangement of the sub-transistors STR may be the same or similar to those in one of the embodiments described with reference to FIGS. 5A to 8B.

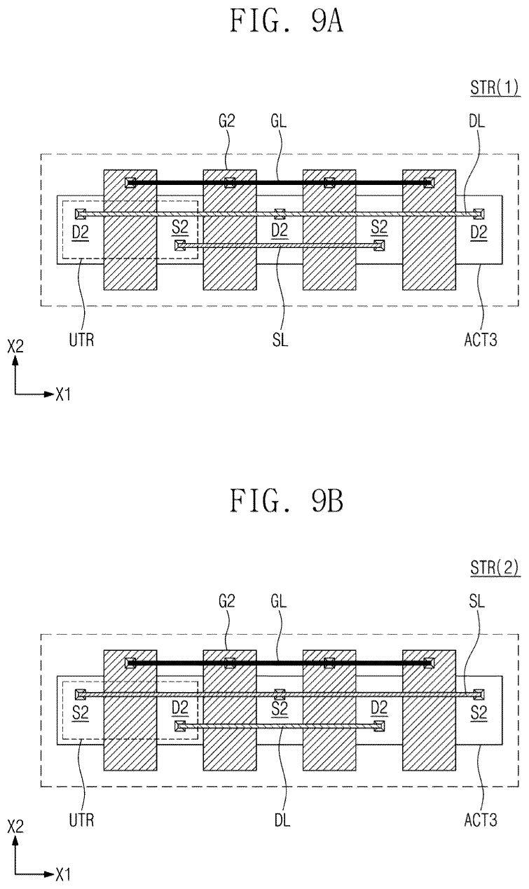

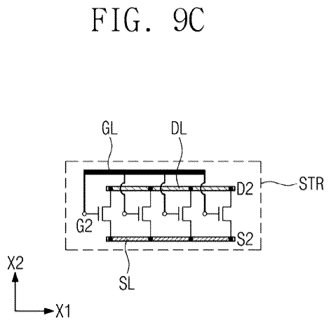

FIGS. 9A and 9B are layouts of a sub-transistor, which includes four unit transistors according to an embodiment. FIG. 9C is a circuit diagram of the sub-transistor of FIG. 9A or 9B.

Referring to FIGS. 9A and 9B, in the case where the sub-transistor STR includes four unit transistors UTR that are connected in parallel, four second gate electrodes G2 may be disposed side by side in the first direction X1, on the third active region ACT3. Five impurity regions S2 and D2 may be disposed in the third active region ACT3. The impurity regions S2 and D2 may include second source regions S2 and second drain regions D2, which may be alternatingly arranged. The arrangement order of the second source and drain regions S2 and D2 may be changed. For example, the impurity regions S2 and D2 may be disposed in the order of S2/D2/S2/D2/S2 in the second sub-transistor STR(2), as shown in FIG. 9B or may be disposed in the order of D2/S2/D2/S2/D2 in the first sub-transistor STR(1), as shown in FIG. 9A. In the second sub-transistor STR(2) of FIG. 9B, the source connection line SL may connect three second source regions S2 to each other. In the first sub-transistor STR(1) of FIG. 9A, the drain connection line DL may connect three second drain regions D2 to each other. The sub-transistor STR of FIGS. 9A and 9B may have the circuit structure shown in FIG. 9C.

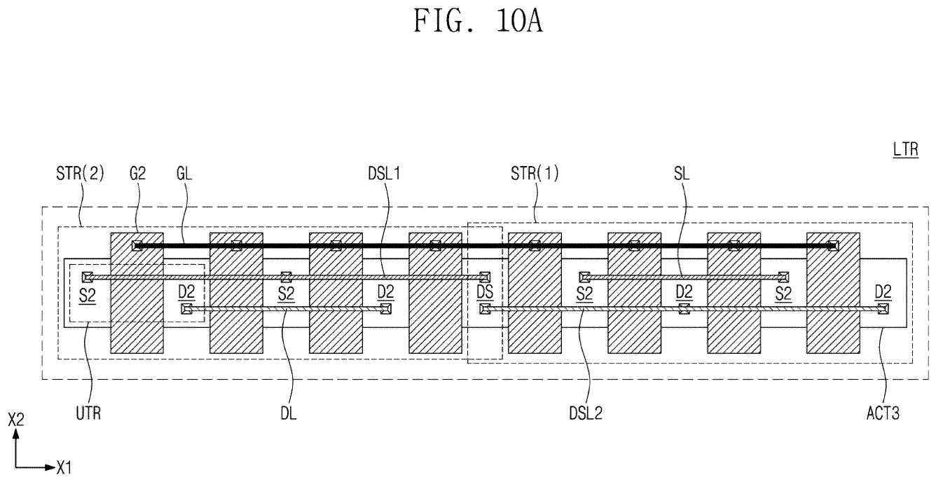

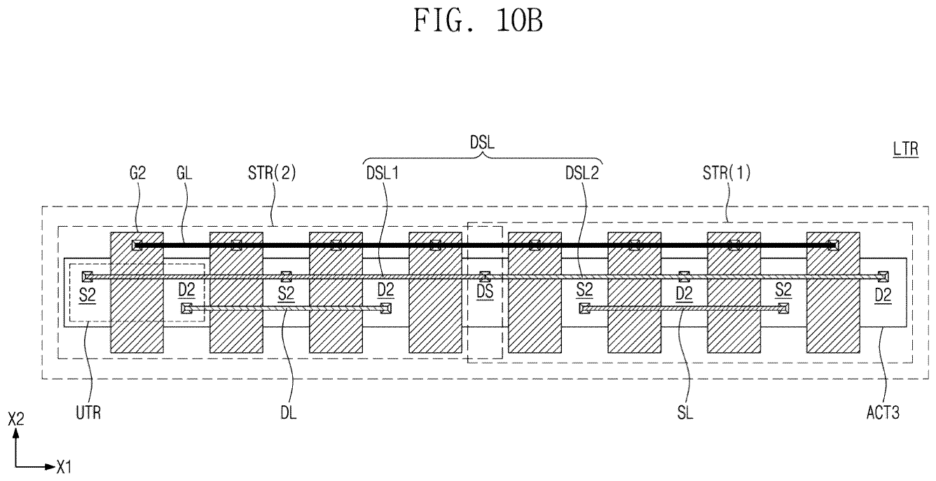

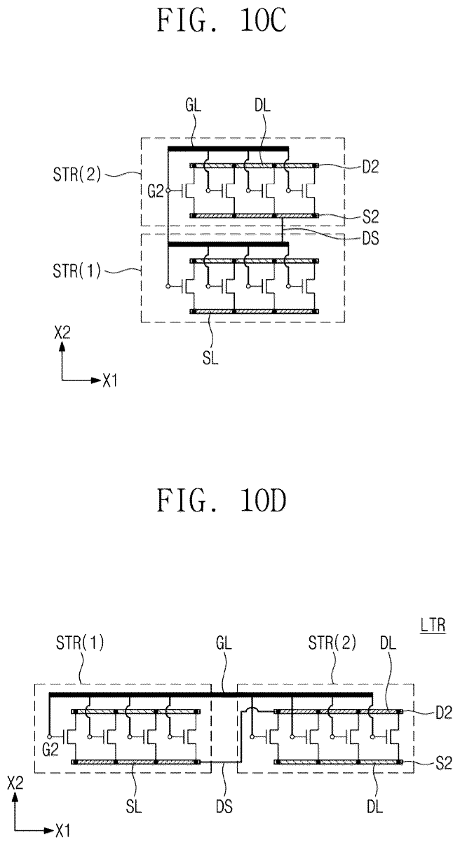

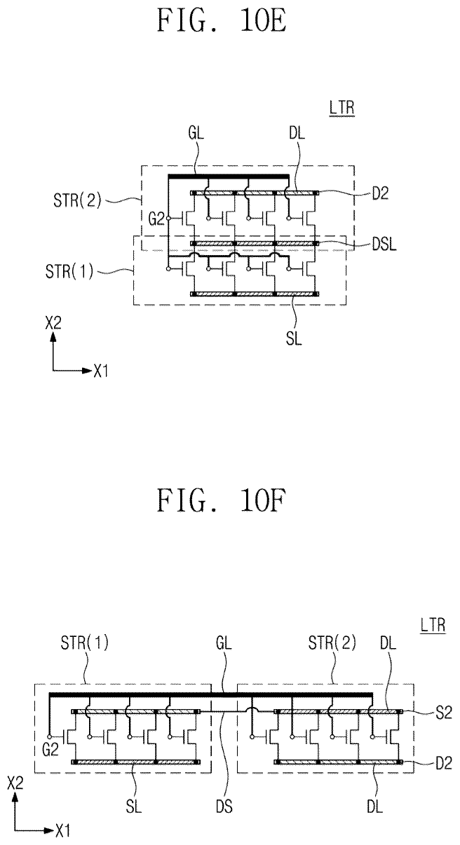

FIGS. 10A and 10B are layouts illustrating a logic transistor according to an embodiment. FIGS. 10A and 10B illustrate two example layouts of a logic transistor LTR that may be constructed by connecting two sub-transistors STR, each of which includes four unit transistors UTR, to each other in the first direction X1.

Referring to FIGS. 10A and 10B, the first sub-transistor STR(1) of FIG. 9A and the second sub-transistor STR(2) of FIG. 9B may be connected to each other in the first direction X1 or the opposite of the first direction X1 to form one logic transistor LTR.

The layouts of the first and second sub-transistors STR(1) and STR(2) may be connected such that the rightmost second source region S2 of the second sub-transistor STR(2) is in contact with, or overlapped with, the leftmost second drain region D2 of the first sub-transistor STR(1).

An overlap region between the first and second sub-transistors STR(1) and STR(2) may serve as the common node region DS. The common node region DS may correspond to the rightmost second source region S2 of the second sub-transistor STR(2) and may correspond to the leftmost second drain region D2 of the first sub-transistor STR(1). The first and second sub-transistors STR(1) and STR(2) may share the common node region DS therebetween.

The logic transistor LTR may include eight second gate electrodes G2 and nine impurity regions S2, D2, and DS, which may be disposed side by side in the first direction X1 on the third active region ACT3.

The source connection line SL of FIG. 9B, which may be used to connect the second source regions S2 in the second sub-transistor STR(2), may serve as the first common node line DSL1 in FIGS. 10A and 10B. For example, the first common node line DSL1 may connect the second source regions S2 of the second sub-transistor STR(2) to the common node region DS.

The drain connection line DL of FIG. 9A, which may be used to connect the second drain regions D2 in the first sub-transistor STR(1), may serve as the second common node line DSL2 in FIGS. 10A and 10B. For example, the second common node line DSL2 may connect the second drain regions D2 in the first sub-transistor STR(1) to the common node region DS.

The common node region DS may connect the first common node line DSL1 to the second common node line DSL2. As a result, it may be unnecessary to form an additional line connecting the first common node line DSL1 to the second common node line DSL2, and thus, the layout may be simplified.

As shown in FIG. 10A, the second common node line DSL2 may be spaced apart from the first common node line DSL1. As shown in FIG. 10B, the first and second common node lines DSL1 and DSL2 may be connected to each other to form the common node line DSL.

FIGS. 10C to 10F are circuit diagrams of the logic transistor of FIG. 10A or 10B.

The logic transistor LTR of FIG. 10A or 10B may be depicted in terms of the circuit diagrams of FIGS. 10C to 10F. For example, the first and second sub-transistors STR(1) and STR(2) may be connected in series, and each of the sub-transistors STR(1) and STR(2) may include four unit transistors UTR that are connected in parallel. The logic transistor LTR of FIG. 10A may have a circuit structure similar to that in FIG. 10C or 10D. The logic transistor LTR of FIG. 10B may have a circuit structure similar to that in FIG. 10E or 10F.

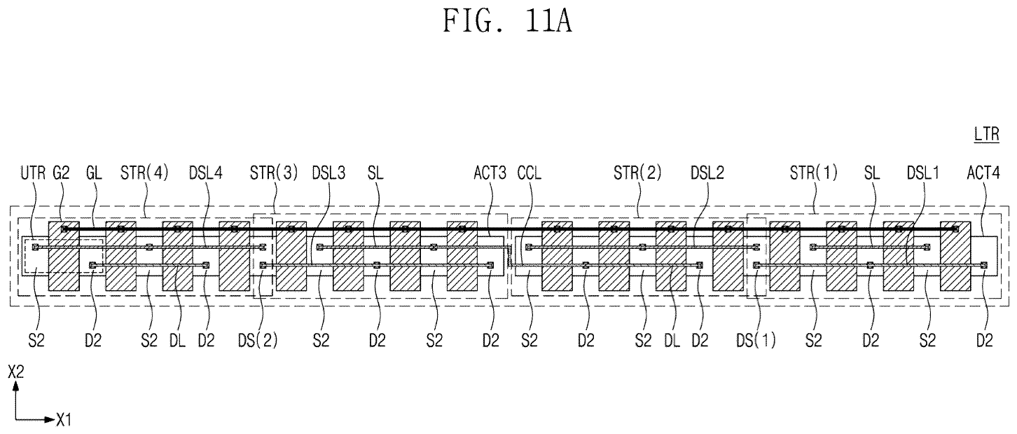

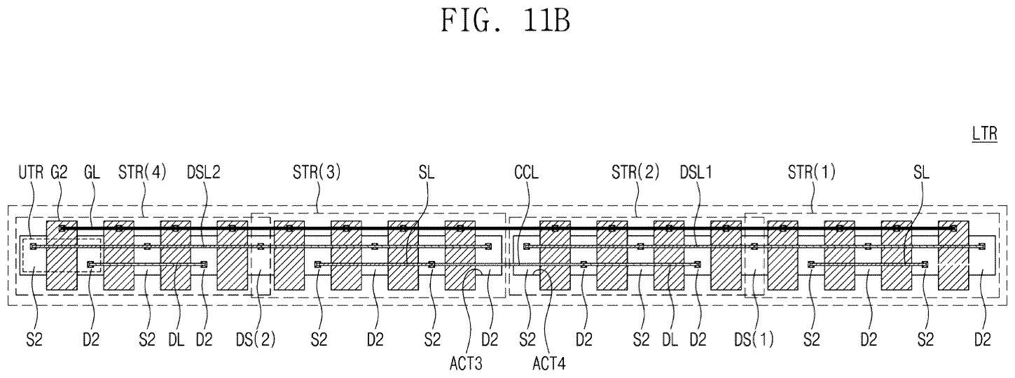

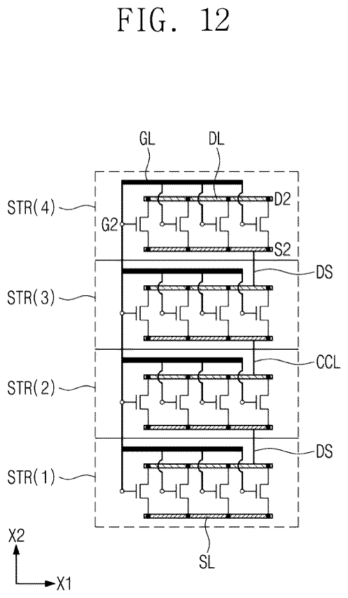

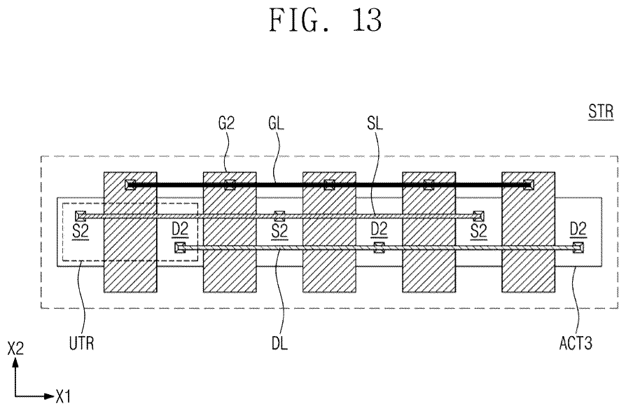

FIGS. 11A and 11B are layouts illustrating a logic transistor according to an embodiment. FIG. 12 is a circuit diagram of the logic transistor of FIG. 11A or 11B.

FIGS. 11A and 11B illustrate two example layouts of a logic transistor LTR that may be constructed by connecting four sub-transistors STR, each of which includes four unit transistors UTR, to each other in the first direction X1 or in the opposite of the first direction X1.

Referring to FIGS. 11A, 11B, and 12, the first to fourth sub-transistors STR(1) to STR(4) may be connected to each other in the first direction X1 or the opposite of the first direction X1 to form one logic transistor LTR. The first and second sub-transistors STR(1) and STR(2) may be disposed on a fourth active region ACT4. The third and fourth sub-transistors STR(3) and STR(4) may be disposed on the third active region ACT3 that is spaced apart from the fourth active region ACT4. The logic transistor LTR may include sixteen second gate electrodes G2 and eighteen impurity regions S2, D2, and DS, which may be disposed side by side in the first direction X1 or in the opposite of the first direction X1.

Each of the first and third sub-transistors STR(1) and STR(3) may have the same layout as the first sub-transistor STR(1) of FIG. 9A. Each of the second and fourth sub-transistors STR(2) and STR(4) may have the same layout as the second sub-transistor STR(2) of FIG. 9B. The connection between the first and second sub-transistors STR(1) and STR(2) may be the same or similar to that in the layout of the logic transistor LTR of FIG. 10A or 10B. The connection between the third and fourth sub-transistors STR(3) and STR(4) may be the same or similar to that in the layout of the logic transistor LTR of FIG. 10A or 10B. In the examples shown in FIGS. 11A and 11B, the logic transistor LTR may further include a node connection line CCL. The node connection line CCL may connect the source connection line SL of the third sub-transistor STR(3) to the drain connection line DL of the second sub-transistor STR(2). When viewed in a plan view, the node connection line CCL may have a bent shape, as shown in FIG. 11A, or may have a straight shape, as shown in FIG. 11B. A source voltage and a drain voltage may not be applied to the node connection line CCL.

FIGS. 9A to 11B illustrate examples in which the sub-transistor STR includes four unit transistors UTR, but embodiments are not limited to this example. The sub-transistor STR may include four or more even-numbered unit transistors UTR. In the case where the sub-transistor STR includes four or more even-numbered unit transistors UTR 4 and four or more sub-transistors STR are connected to form a row parallel to the first direction X1, the active region ACT3 for the first and second sub-transistors STR(1) and STR(2) may be separated from the active region ACT4 for the third and fourth sub-transistors STR(3) and STR(4) as shown in FIGS. 11A and 11B.

In the present disclosure, each of the unit transistors UTR may have the shape of a planar FET, but embodiments are not limited to this example. Each of the unit transistors UTR may be provided in the form of a FinFET, a Vertical FET, a multi-bridge-channel FET (MBCFET), or a gate-all-around FET (GAAFET).

FIG. 13 is a layout of a sub-transistor, which includes five unit transistors according to an embodiment.

Referring to FIG. 13, the sub-transistor STR may include five unit transistors UTR that are connected in parallel. Five second gate electrodes G2 may be disposed side by side in the first direction X1, on the third active region ACT3. Six impurity regions S2 and D2 may be disposed in the third active region ACT3. The impurity regions S2 and D2 may include second source regions S2 and second drain regions D2, which may be alternatingly arranged. The arrangement order of the second source and drain regions S2 and D2 may be changed. The source connection line SL may connect three second source regions S2 to each other. The drain connection line DL may connect three second drain regions D2 to each other.

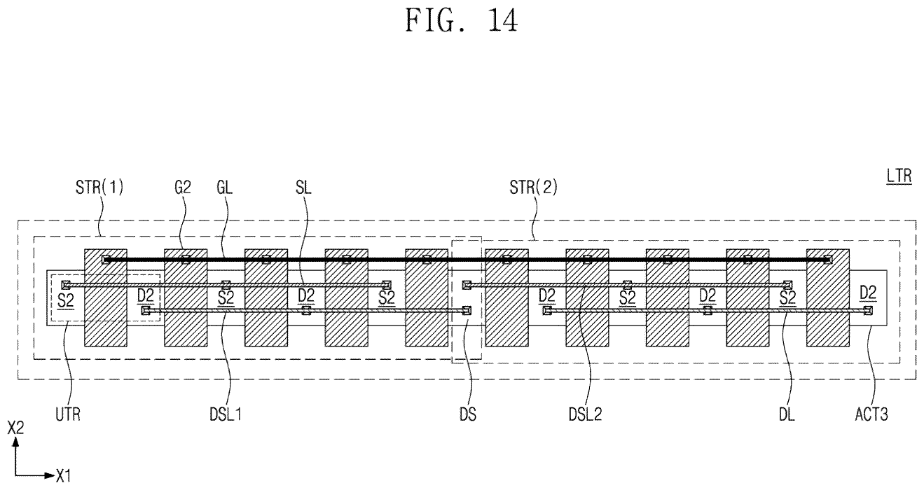

FIG. 14 is a layout illustrating a logic transistor according to an embodiment. FIG. 14 illustrates an example layout of a logic transistor LTR that may be constructed by connecting two sub-transistors STR, each of which includes five unit transistors UTR, to each other in the first direction X1.

Referring to FIG. 14, the logic transistor LTR may include ten second gate electrodes G2 and eleven impurity regions S2, D2, and DS, which are arranged side by side in the first direction X1, on the third active region ACT3. In the example shown in FIG. 14, the common node region DS may connect the first common node line DSL1 to the second common node line DSL2. As a result, it may be unnecessary to form an additional line connecting the first common node line DSL1 to the second common node line DSL2, and thus, the layout may be simplified. Other portions may be the same or similar to those in one of the embodiments described with reference to FIG. 5A to 8B.

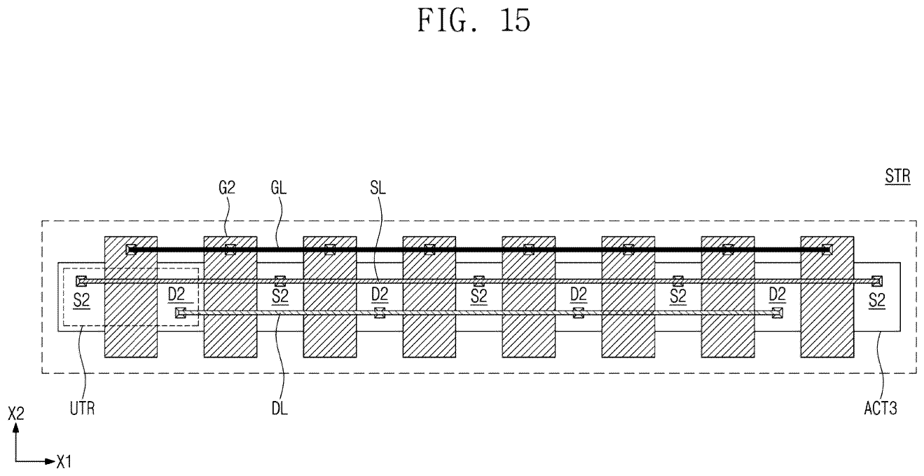

FIG. 15 is a layout of a sub-transistor, which includes eight unit transistors according to an embodiment.

Referring to FIG. 15, the sub-transistor STR may include eight unit transistors UTR that are connected in parallel. Eight second gate electrodes G2 may be disposed side by side in the first direction X1, on the third active region ACT3. Nine impurity regions S2 and D2 may be disposed in the third active region ACT3. The impurity regions S2 and D2 may include second source regions S2 and second drain regions D2, which may be alternatingly arranged. The arrangement order of the second source and drain regions S2 and D2 may be changed. The source connection line SL may connect five second source regions S2 to each other. The drain connection line DL may connect four second drain regions D2 to each other. The connection structure between the unit transistors UTR in the sub-transistor STR of FIG. 15 may be different from that in the examples shown in FIGS. 10A and 10B. A plurality of sub-transistors having the same structure as the sub-transistor STR of FIG. 15 may be disposed in the first direction X1 and may be connected to each other in the same manner as that in one of the embodiments of FIGS. 10A to 11B.

The layout of the logic transistor may be designed in the manner described above. The number of the sub-transistors and the number of the unit transistors included in each sub-transistor may not be limited to those in the examples shown in FIGS. 4 to 15. The number of the sub-transistors included in the logic transistor may be greater than or equal to 2, and the number of the unit transistors included in each sub-transistor may be greater than or equal to 3.

The logic transistor LTR, which may be fabricated to have the layout structure designed by the layout design method described above, may be applied to various semiconductor devices. For example, the logic transistor LTR may be applied to an image sensor or various memory devices (e.g., a DRAM device). The logic transistor LTR may be used as a part of a circuit (e.g., an analog-to-digital converter (ADC), a row driver, or a column decoder) of the image sensor. In some embodiments, the logic transistor LTR may be used as a part of a circuit (e.g., a sub-word line driver or a sense amplifier) of a DRAM device or as a part of a circuit (e.g., a decoder or a page buffer) of a NAND FLASH memory device.

Below, an example of an image sensor including the logic transistor is described in more detail.

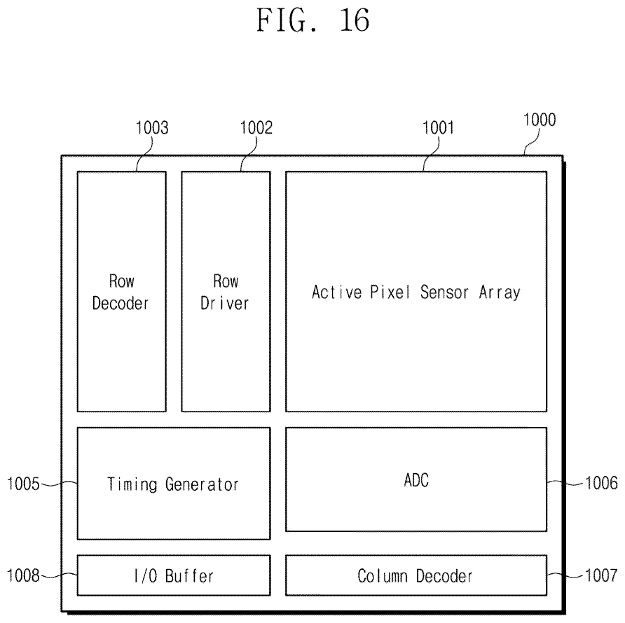

FIG. 16 is a block diagram illustrating an image sensor according to an embodiment.

Referring to FIG. 16, an image sensor 1000 may be a semiconductor configured to convert an optical image to electric signals. The image sensor 1000 may be configured to generate digital signals from light that is incident from the outside. In an electronic device including the image sensor 1000, the digital signals may be used to display images on a display panel. In an embodiment, the electronic device including the image sensor 1000 may be realized as one of various electronic devices including smartphones, tablet personal computers, laptop personal computers, wearable devices, or the like.

The image sensor 1000 may include an active pixel sensor array 1001, a row driver 1002, a row decoder 1003, a column decoder 1007, a timing generator 1005, an analog-to-digital converter (ADC) 1006, and an input/output (I/O) buffer 1008.

The active pixel sensor array 1001 may include a plurality of pixels, which may be two-dimensionally arranged, and may be configured to convert an optical signal to an electrical signal. The active pixel sensor array 1001 may be driven by a plurality of driving signals, such as a pixel selection signal, a reset signal, and a charge transfer signal, which are transmitted from the row driver 1002. The converted electrical signal may be provided to a correlated double sampler.

The row driver 1002 may be configured to generate driving signals for driving unit pixels, based on information decoded by the row decoder 1003, and then to transmit such driving signals to the active pixel sensor array 1001. In the case where the unit pixels are arranged in a matrix shape (e.g., in rows and columns), the driving signals may be provided to respective rows.

The timing generator 1005 may be configured to provide timing signals and control signals to the row decoder 1003 and the column decoder 1007.

The ADC 1006 may be configured to serve as a correlated double sampler (CDS). The correlated double sampler may be configured to receive electric signals, which may be generated in the active pixel sensor array 1001, and to perform an operation of holding and sampling the received electric signals. For example, the correlated double sampler may perform a double sampling operation, in which a specific noise level and a signal level of the electric signal may be used, and then output a difference level corresponding to a difference between the noise and signal levels. In an embodiment, the ADC 1006 may be configured to convert an analog signal, which may contain information on the difference level outputted from the correlated double sampler, to a digital signal and to output the converted digital signal.

The I/O buffer 1008 may be configured to latch the digital signals and then to sequentially output the latched signals to an image signal processing unit, based on information decoded by the column decoder 1007.

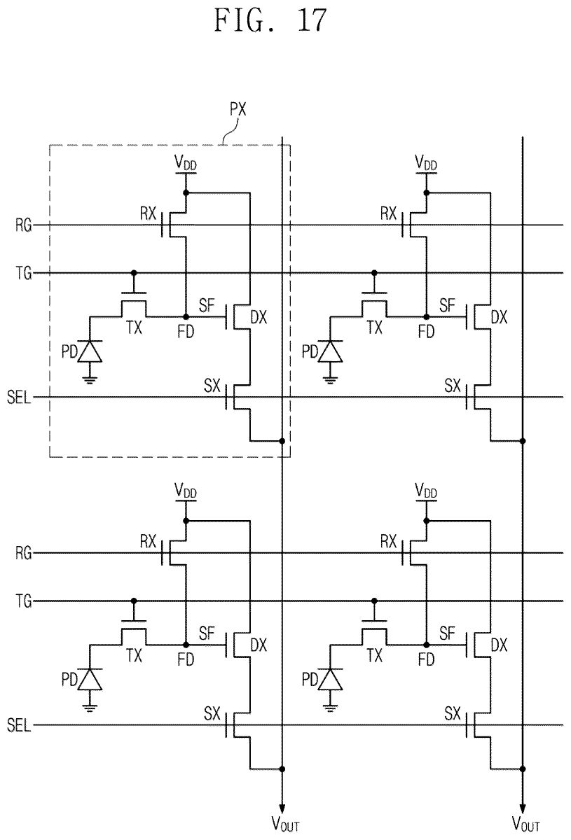

FIG. 17 is a circuit diagram illustrating an active pixel sensor array of an image sensor according to an embodiment.

Referring to FIGS. 16 and 17, the active pixel sensor array 1001 may include a plurality of unit pixels PX, which may be arranged in a matrix shape. Each of the unit pixels PX may include a transfer transistor TX. Each of the unit pixels PX may further include a pixel transistor, for example a reset transistor RX, a selection transistor SX, or a source follower transistor DX. The transfer transistor TX may include a transfer gate TG. Each of the unit pixels PX may further include a photoelectric conversion region PD and a floating diffusion region FD. In an embodiment, the pixel transistors may be shared by at least two of the unit pixels PX.

The photoelectric conversion region PD may be configured to generate photocharges in an amount is proportional to an amount of light incident from the outside and to store the photocharges. The photoelectric conversion region PD may include a photo diode, a photo transistor, a photo gate, a pinned photo diode, or any combination thereof. The transfer transistor TX may be configured to transfer electric charges, which are generated in the photoelectric conversion region PD, to the floating diffusion region FD. The floating diffusion region FD may be configured to receive and cumulatively store the electric charges, which are generated in the photoelectric conversion region PD. The source follower transistor DX may be controlled, based on an amount of photocharges stored in the floating diffusion region FD.

The reset transistor RX may be configured to periodically discharge or reset the photocharges accumulated in the floating diffusion region FD. The reset transistor RX may include drain and source electrodes, which may be connected to the floating diffusion region FD and a power voltage VDD, respectively. When the reset transistor RX is turned on, the power voltage VDD, which may be connected to the source electrode of the reset transistor RX, may be applied to the floating diffusion region FD. Thus, if the reset transistor RX is turned on, the electric charges accumulated in the floating diffusion region FD may be discharged; for example, the floating diffusion region FD may be reset.

The source follower transistor DX including a source follower gate electrode SF may be used as a source follower buffer amplifier. The source follower transistor DX may be configured to amplify a variation in electric potential of the floating diffusion region FD and to output the amplified signal to an output line Vout.

The selection transistor SX including a selection gate electrode SEL may be used to select one of the rows of the unit pixels PX, during reading operations. When the selection transistor SX is turned on, the power voltage VDD may be applied to a drain electrode of the source follower transistor DX.

FIG. 17 illustrates an example of a unit pixel PX, in which the transfer transistor TX, the reset transistor RX, the selection transistor SX, and the source follower transistor DX are disposed, but embodiments are not limited to this example. For example, at least one of the reset transistor RX, the selection transistor SX, and the source follower transistor DX may be shared by a plurality of unit pixels PX.

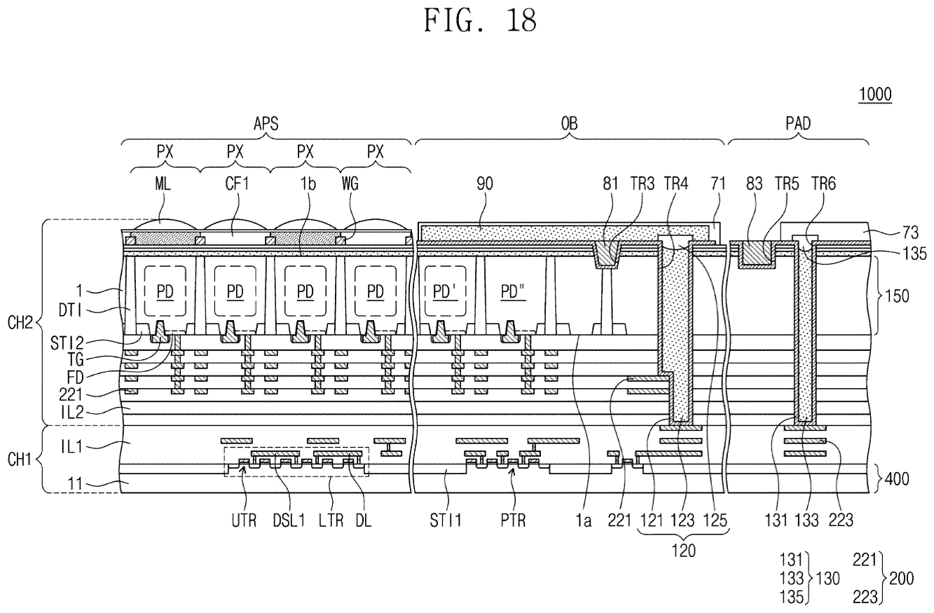

FIG. 18 is a sectional view illustrating an image sensor according to an embodiment.

Referring to FIG. 18, an image sensor 1000 according to an embodiment may include a first semiconductor chip CH1 and a second semiconductor chip CH2 that are sequentially stacked. The first semiconductor chip CH1 may include a first substrate 11, a lower interconnection layer 223, and a first interlayer insulating layer IL1. A first device isolation portion STI1 may be disposed on the first substrate 11 to confine active regions. Circuits, which may correspond to the row driver 1002, the row decoder 1003, the column decoder 1007, the timing generator 1005, the ADC 1006, and the I/O buffer 1008 of FIG. 16, may be disposed on the first substrate 11. Peripheral transistors PTR, logic transistors LTR, and a lower interconnection layer 223 may be disposed on the first substrate 11 of the first semiconductor chip CH1 to form the circuits, such as the row driver 1002, the row decoder 1003, the column decoder 1007, the timing generator 1005, the ADC 1006, and the I/O buffer 1008. However, embodiments are not limited to the example of FIG. 18, and the logic transistors LTR may be disposed in the second semiconductor chip CH2.

FIG. 19 is a plan view schematically illustrating an ADC circuit region according to an embodiment.

Referring to FIG. 19, an ADC circuit region 1006a according to the present embodiment may include a plurality of ADC column regions AC (for example, AC(1), AC(2), . . . AC(K−1), AC(K)). The ADC circuit region 1006a is a region where the ADC 1006 is disposed. The ADC column region AC is a region where an ADC column is disposed. The ADC column regions AC may be provided to have a structure elongated in the first direction X1 and may be arranged side by side in the second direction X2. In an embodiment, K ADC column regions AC may be included in the ADC circuit region 1006a. The number K of the K ADC column regions AC may be equal to the column number of the pixels PX included in the active pixel sensor array 1001. Each of the ADC column regions AC may have the third width W3 in the second direction X2. This means that the ADC circuit region 1006a may have a fourth width W4 that is K times the third width W3, in the second direction X2.

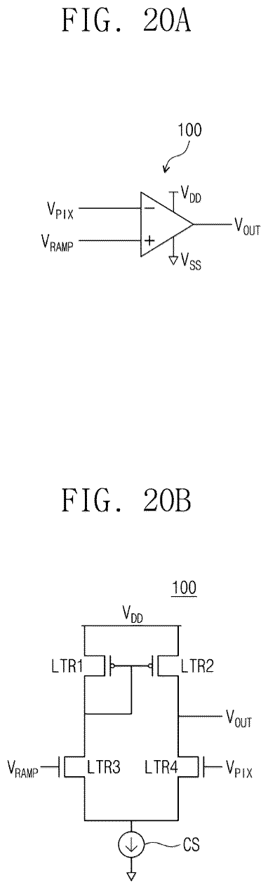

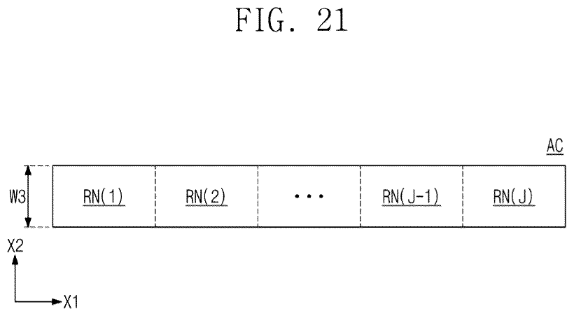

FIG. 20A illustrates a portion of an ADC circuit. FIG. 20B is a detailed circuit diagram of a comparator of FIG. 20A.

Referring to FIGS. 19, 20A, and 20B, a comparator 100 may be disposed in each of the ADC column regions AC, as shown in FIG. 20A. The comparator 100 may include a first logic transistor LTR1, a second logic transistor LTR2, a third logic transistor LTR3, a fourth logic transistor LTR4, and a current source CS, as shown in FIG. 20B. The first and second logic transistors LTR1 and LTR2 may be load transistors and may be, for example, p-type MOSFETs. The power voltage VDD may be applied to end portions of the first and second logic transistors LTR1 and LTR2. The gate electrodes of the first and second logic transistors LTR1 and LTR2 may be connected to each other. The third and fourth logic transistors LTR3 and LTR4 may be input transistors and may be, for example, n-type MOSFETs. A ramp voltage VRamp may be applied to the gate electrode of the third logic transistor LTR3. A pixel voltage VPix may be applied to the gate electrode of the fourth logic transistor LTR4. The current source CS may be provided between and connected to the third and fourth logic transistors LTR3 and LTR4. An output node Vout may be provided between and connected to the second and fourth logic transistors LTR2 and LTR4.

FIG. 21 is a schematic plan view of an ADC column region.

Referring to FIG. 21, each of the ADC column regions AC of FIG. 19 may include J transistor regions RN (for example, RN(1), RN(2), . . . , RN(J−1), RN(J)), where J is a natural number that is greater than or equal to 5. The transistor regions RN may be arranged side by side in the first direction X1. Transistor regions RN, which are arranged to form a row in the first direction X1, may be disposed in each ADC column region AC, as shown in FIG. 21. However, embodiments are not limited to this example, and the transistor regions RN in each ADC column region AC may be arranged to form a plurality of rows in the first direction X1.

The first to fourth logic transistors LTR1 to LTR4 of FIG. 20B may be disposed in at least one of the transistor regions RN. For example, the first logic transistor LTR1 may be disposed in a first transistor region RN(1). The second logic transistor LTR2 may be disposed in a second transistor region RN(2). The third logic transistor LTR3 may be disposed in a (J−1)-th transistor region RN(J−1). The fourth logic transistor LTR4 may be disposed in a J-th transistor region RN(J). The arrangement of the first to fourth logic transistors LTR1 to LTR4 is not limited to this example and may be variously modified.

According to embodiments of the present disclosure, each of the first to fourth logic transistors LTR1 to LTR4 may have the layout or structure of the logic transistor LTR described with reference to FIGS. 3A to 15. Thus, it may be possible to reduce the width W3 of each of the ADC column regions AC in the second direction X2 and the width W4 of the ADC circuit region 1006a in the second direction X2, and in this case, the size of the image sensor 1000 may be reduced. Accordingly, it may be possible to increase the integration density of the image sensor 1000.

Referring again to FIG. 18, the second semiconductor chip CH2, which is disposed on the first semiconductor chip CH1, may include a second substrate 1 with a main region APS, an optical black region OB, and a pad region PAD. An upper interconnection layer 221 and a second interlayer insulating layer IL2 may be disposed on a front surface 1a of the second substrate 1. The main region APS may include a plurality of pixels PX. A deep isolation portion DTI may be disposed in the second substrate 1 to separate the photoelectric conversion regions PD of pixels PX from each other. The deep isolation portion DTI may have a mesh shape, when viewed in a plan view. The deep isolation portion DTI may include an isolation conductive pattern, which is spaced apart from the second substrate 1, and an isolation insulating pattern, which is interposed between the isolation conductive pattern and the second substrate 1. A second device isolation portion STI2 may be disposed in the second substrate 1 to confine active regions. The deep isolation portion DTI may penetrate the second device isolation portion STI2. No interface may be observed between the deep isolation portion DTI and the second device isolation portion STI2.

In each of the pixels PX, the photoelectric conversion region PD may be disposed in the second substrate 1. In each of the pixels PX, the transfer gate TG and the floating diffusion region FD may be disposed on and in the front surface 1a of the second substrate 1. A color filter array, which may include color filters CF1, may be disposed on a rear surface 1b of the second substrate 1. A micro lens array, which includes micro lenses ML, may be disposed on the color filter array.

At least one of the first to fourth logic transistors LTR1 to LTR4 may be overlapped with at least one of the pixels PX, the photoelectric conversion region PD, the transfer gate TG, and the floating diffusion region FD.

In the optical black region OB, a light-blocking pattern WG, a first connection structure 120, a first conductive pad 81, and a bulk color filter 90 may be provided on the second substrate 1. The first connection structure 120 may include a first connection line 121, an insulating pattern 123, and a first capping pattern 125.

A portion of the first connection line 121 may be provided on the rear surface 1b of the second substrate 1 and may conformally cover inner surfaces of third and fourth trenches TR3 and TR4. The light-blocking pattern WG may cover the rear surface 1b. The first connection line 121 may be provided to penetrate a photoelectric conversion layer 150 and the upper interconnection layer 221 and to connect the photoelectric conversion layer 150 to an interconnection layer 200. More specifically, the first connection line 121 may be in contact with the interconnection lines, which may be provided in the upper and lower interconnection layers 221 and 223, and the isolation conductive pattern of the deep isolation portion DTI, which may be provided in the photoelectric conversion layer 150. Thus, the first connection structure 120 may be electrically connected to interconnection lines in the interconnection layer 200. The first connection line 121 may be formed of or include at least one of metallic materials (e.g., tungsten). The light-blocking pattern WG may prevent light from being incident into the optical black region OB.

The first conductive pad 81 may be provided in the third trench TR3 to fill a remaining portion of the third trench TR3. The first conductive pad 81 may be formed of or include at least one of metallic materials (e.g., aluminum). The first conductive pad 81 may be in contact with the isolation conductive pattern of the deep isolation portion DTI. A negative bias voltage may be applied to the isolation conductive pattern, which is disposed in the deep isolation portion DTI, through the first conductive pad 81. In this case, it may be possible to prevent or suppress a white spot issue or a dark current issue.

The insulating pattern 123 may fill a remaining portion of the fourth trench TR4. The insulating pattern 123 may be provided to penetrate the photoelectric conversion layer 150 and the entirety or at least a portion of the interconnection layer 200. The first capping pattern 125 may be provided on a top surface of the insulating pattern 123. The first capping pattern 125 may be provided on the insulating pattern 123.

The bulk color filter 90 may be provided on the first conductive pad 81, the light-blocking pattern WG, and the first capping pattern 125. The bulk color filter 90 may cover the first conductive pad 81, the light-blocking pattern WG, and the first capping pattern 125. A first protection layer 71 may be provided on the bulk color filter 90 to hermetically seal the bulk color filter 90.

A photoelectric conversion region PD′ and a dummy region PD″ may be provided in the optical black region OB of the second substrate 1. In an embodiment, the photoelectric conversion region PD′ may be doped with impurities of a second conductivity type different from a first conductivity type. The second conductivity type may be, for example, an n-type. The photoelectric conversion region PD′ may have a structure similar to the photoelectric conversion region PD but may not be used to execute the operation (e.g., generating electrical signals from the incident light), which is executed by the photoelectric conversion region PD. The dummy region PD″ may not be doped with impurities. The signals which are generated in the dummy region PD″ may be used as the information for removing a process noise.

In the pad region PAD, a second connection structure 130, a second conductive pad 83, and a second protection layer 73 may be provided on the second substrate 1. The second connection structure 130 may include a second connection line 131, an insulating pattern 133, and a second capping pattern 135.

The second connection line 131 may be provided on the rear surface 1b of the second substrate 1. For example, the second connection line 131 may cover the rear surface 1b and may conformally cover inner surfaces of fifth and sixth trenches TR5 and TR6. The second connection line 131 may be provided to penetrate the photoelectric conversion layer 150 and the upper interconnection layer 221 and to connect the photoelectric conversion layer 150 to the interconnection layer 200. For example, the second connection line 131 may be in contact with the interconnection lines in the lower interconnection layer 223. Accordingly, the second connection structure 130 may be electrically connected to the interconnection lines in the interconnection layer 200. The second connection line 131 may be formed of or include at least one of metallic materials (e.g., tungsten).

The second conductive pad 83 may be provided in the fifth trench TR5 to fill a remaining portion of the fifth trench TR5. The second conductive pad 83 may be formed of or include at least one of metallic materials (e.g., aluminum). The second conductive pad 83 may be used as a conduction path, which may be used for electric connection to the outside of the image sensor. The insulating pattern 133 may fill a remaining portion of the sixth trench TR6. The insulating pattern 133 may be provided to penetrate the photoelectric conversion layer 150 and the entirety or at least a portion of the interconnection layer 200. The second capping pattern 135 may be provided on the insulating pattern 133.

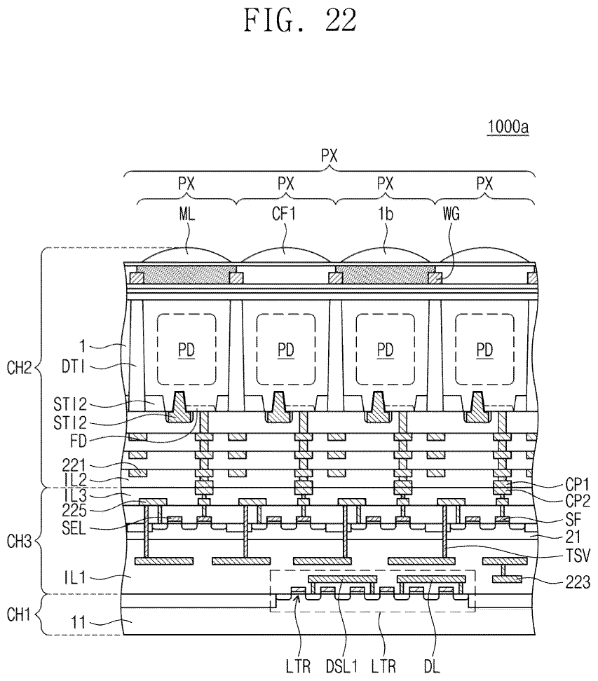

FIG. 22 is a sectional view illustrating an image sensor according to an embodiment.

Referring to FIG. 22, an image sensor 1000a may include a third semiconductor chip CH3, which is interposed between the first semiconductor chip CH1 and the second semiconductor chip CH2. The third semiconductor chip CH3 may include a third substrate 21 and may further include an intermediate interconnection layer 225 and a third interlayer insulating layer IL3, which are disposed on the third substrate 21. A first chip connection pad CP1 may be disposed in a lower portion of the second semiconductor chip CH2. A second chip connection pad CP2 may be disposed in an upper portion of the third semiconductor chip CH3. The second chip connection pad CP2 may be in contact with the first chip connection pad CP1. A source follower gate SF and a selection gate SEL may be disposed on the third substrate 21. The third semiconductor chip CH3 may be connected to the first semiconductor chip CH1 through a penetration via TSV. The logic transistors LTR may be integrated on the first semiconductor chip CH1. However, embodiments are not limited to this example, and the logic transistors LTR may be provided on the second semiconductor chip CH2 and/or the third semiconductor chip CH3. In an embodiment, as shown in FIG. 22, at least one of the source follower gate SF and the selection gate SEL may be overlapped with at least one of the logic transistors LTR. Other portions may have the same or similar structural features to those in one of the embodiments described above.

In the specification, a concept of individual semiconductor chips may be defined by a stacked structure formed by several semiconductor wafers which are different from each other. An interface between the semiconductor chips may not be definitely observed because of bonding shape, bonding method, or bonding material between the semiconductor chips, and the stacked structure having an ambiguous interface is not excluded from the concept of the individual semiconductor chips.

In a layout design method according to an embodiment, a logic transistor may be divided in a plurality of logic transistors, which may be placed in a finger shape. In this case, it may be possible to reduce a width of an active region for the logic transistor, to reduce an area occupied by interconnection lines, and to reduce the complexity and difficulty in a process of placing the interconnection structure.

Furthermore, in the case where a logic transistor has a layout designed by the layout design method described above, it may be possible to reduce a width of an active region and to reduce an area occupied by connection lines. This may make it possible to increase an integration density of a semiconductor device, such as an image sensor.

While example embodiments have been particularly shown and described, it will be understood by one of ordinary skill in the art that variations in form and detail may be made therein without departing from the spirit and scope of the attached claims. At least two of the examples described above with reference to FIGS. 3A to 22 may be combined according to embodiments.

1. A semiconductor device, comprising:
a first substrate;
a first device isolation portion in the first substrate around a first active region extending in a first direction;
a plurality of sub-transistors disposed adjacently in the first direction on the first active region, wherein the plurality of sub-transistors are connected to form a logic transistor; and
a common node region in the first active region, wherein the common node region is shared by the plurality of sub-transistors,
wherein each sub-transistor of the plurality of sub-transistors comprises:
at least three gate electrodes which cross the first active region in a second direction and which are spaced apart in the first direction, wherein the second direction intersects the first direction; and
a plurality of source regions and a plurality of drain regions disposed in the first active region adjacent to sidewalls of the at least three gate electrodes, wherein the plurality of source regions are alternatingly arranged with the plurality of drain regions in the first direction, and
wherein the common node region is disposed at a center of the first active region.

2. The semiconductor device of claim 1, wherein the plurality of sub-transistors comprises a plurality of first sub-transistors and a plurality of second sub-transistors which are disposed adjacently in the first direction,
wherein the semiconductor device further comprises:
a gate connection line connecting gate electrodes of the plurality of first sub-transistors and the plurality of second sub-transistors, wherein the gate connection line extends in the first direction;
a source connection line connecting source regions of the plurality of first sub-transistors;
a drain connection line connecting drain regions of the plurality of second sub-transistors;
a first common node line connecting drain regions of the plurality of first sub-transistors to the common node region; and
a second common node line connecting source regions of the plurality of second sub-transistors to the common node region.

3. The semiconductor device of claim 2, wherein a gate voltage is applied to the gate electrodes,
wherein a source voltage is applied to the source connection line,
wherein a drain voltage is applied to the drain connection line, and
wherein the source voltage and the drain voltage are not applied to the first common node line and the second common node line.

4. The semiconductor device of claim 2, wherein the source connection line and the second common node line are arranged along a first straight line,
wherein the first common node line and the drain connection line are arranged along a second straight line, and
wherein the first straight line is spaced apart from the second straight line in the second direction.

5. The semiconductor device of claim 2, wherein the source connection line and the drain connection line are arranged along a first straight line,
wherein the first common node line and the second common node line are arranged along a second straight line and are connected to each other, and
wherein the first straight line is spaced apart from the second straight line in the second direction.

6. The semiconductor device of claim 2, further comprising:
a first contact plug connecting the common node region to the first common node line; and
a second contact plug connecting the common node region to the second common node line,
wherein the first contact plug is spaced apart from the second contact plug in the second direction.

7. The semiconductor device of claim 1, wherein the first active region has a first width in the second direction,
wherein each gate electrode of the at least three gate electrodes has a second width in the second direction, wherein the second width is larger than the first width,
wherein the each gate electrode has a third width in the first direction, and
wherein the at least three gate electrodes are spaced apart by a first distance.

8. An image sensor, comprising:
a first substrate comprising an analog-to-digital converter (ADC) circuit region comprising a plurality of ADC column regions;
a device isolation portion in the first substrate around a plurality of active regions in each of the plurality of ADC column regions;
a plurality of logic transistors in the plurality of active regions;
a plurality of interconnection lines connecting the plurality of logic transistors;
a first interlayer insulating layer on the plurality of logic transistors, the plurality of interconnection lines, and the first substrate;
a second interlayer insulating layer on the first interlayer insulating layer;
a second substrate on the second interlayer insulating layer, wherein the second substrate comprises a plurality of photoelectric conversion regions;
a deep isolation portion in the second substrate, wherein the deep isolation portion separates the plurality of photoelectric conversion regions; and
a color filter array and a micro lens array sequentially stacked on the second substrate,
wherein the plurality of ADC column regions is arranged in a first direction,
wherein each ADC column region of the plurality of ADC column regions and each active region of the plurality of active regions extends in a second direction intersecting the first direction,
wherein, in the each ADC column region, the plurality of active regions is arranged in the second direction to form a column,
wherein each logic transistor of the plurality of logic transistors comprises M sub-transistors disposed in the second direction on a corresponding active region from among the plurality of active regions, where M is an integer greater than or equal to two (“2”),
wherein the each sub-transistor comprises N unit transistors disposed in the second direction, where N is an integer greater than or equal to three (“3”),
wherein each unit transistor of the N unit transistors comprises a gate electrode, and a source region and a drain region adjacent to the gate electrode,
wherein at least one of the source region and the drain region between adjacent unit transistors is shared by the adjacent unit transistors, and
wherein a common node region is disposed in a corresponding active region to connect the M sub-transistors.

9. The image sensor of claim 8, wherein, in the each unit transistor, the gate electrode crosses the corresponding active region in the first direction, and
wherein the gate electrode of the each unit transistor has a unit gate width and a unit gate length.

10. The image sensor of claim 8, wherein the plurality of active regions comprises a first active region,
wherein the first active region comprises a first sidewall and a second sidewall opposite to the first sidewall in the second direction,
wherein a first logic transistor from among the plurality of logic transistors is on the first active region, and
wherein the M sub-transistors included in the first logic transistor comprises a first sub-transistor closest to the first sidewall and a second sub-transistor closest to the second sidewall, and
wherein the image sensor further comprises:
a gate connection line connecting the gate electrode of the each unit transistor included in the first logic transistor in the second direction;
a source connection line connecting the source region of the each unit transistor included in the first sub-transistor;
a drain connection line connecting the drain region of the each unit transistor included in the second sub-transistor;
a first common node line connecting the drain region of the each unit transistor included in the first sub-transistor to the common node region; and
a second common node line connecting the source region of the each unit transistor included in the second sub-transistor to the common node region.

11. The image sensor of claim 10, wherein a source voltage is applied to the source connection line,
wherein a drain voltage is applied to the drain connection line, and
wherein the source voltage and the drain voltage are not applied to the first common node line and the second common node line.

12. The image sensor of claim 10, wherein the source connection line and the second common node line are arranged along a first straight line,
wherein the first common node line and the drain connection line are arranged along a second straight line, and
wherein the first straight line is spaced apart from the second straight line in the first direction.

13. The image sensor of claim 10, wherein the source connection line and the drain connection line are arranged along a first straight line,
wherein the first common node line and the second common node line are arranged along a second straight line and are connected to each other, and
wherein the first straight line is spaced apart from the second straight line in the first direction.

14. The image sensor of claim 10, further comprising:
a first contact plug connecting the common node region to the first common node line; and
a second contact plug connecting the common node region to the second common node line,
wherein the first contact plug is spaced apart from the second contact plug in the first direction.

15. The image sensor of claim 8, wherein at least one pixel of the plurality of photoelectric conversion regions is overlapped with at least one ADC column region of the plurality of ADC column regions.

16. The image sensor of claim 8, further comprising:
a transfer gate electrode below the second substrate;
a floating diffusion region disposed in the second substrate;
a third substrate between the first interlayer insulating layer and the second interlayer insulating layer;
a source follower gate electrode on the third substrate and connected to the floating diffusion region; and
a selection gate electrode on the third substrate.

17. A semiconductor device, comprising:
a first substrate;
a first device isolation portion in the first substrate around a first active region that extending in a first direction;
a plurality of sub-transistors disposed in the first direction on the first active region, wherein the plurality of sub-transistors connected to form a logic transistor;
a common node region in the first active region, wherein the common node region is shared by the plurality of sub-transistors; and
a first contact plug and a second contact plug on the common node region, wherein the first contact plug is spaced apart from the second contact plug in a second direction intersecting the first direction,
wherein the common node region is located at a center of the first active region.

18. The semiconductor device of claim 17, wherein each sub-transistor of the plurality of sub-transistors comprises:
at least three gate electrodes which cross the first active region in the second direction, and which are spaced apart in the first direction; and
a plurality of source regions and a plurality of drain regions disposed in the first active region adjacent to sidewalls of the at least three gate electrodes, wherein the plurality of source regions are alternatingly arranged with the plurality of drain regions in the first direction,
wherein the first active region has a first width in the second direction,
wherein each gate electrode of the at least three gate electrodes has a second width in the second direction, wherein the second width is larger than the first width,
wherein the each gate electrode has a third width in the first direction, and
wherein the at least three gate electrodes are spaced apart by a first distance.

19. The semiconductor device of claim 18, wherein the first active region comprises a first sidewall and a second sidewall opposite to the first sidewall in the first direction, and
wherein the plurality of sub-transistors comprises a first sub-transistor closest to the first sidewall, and a second sub-transistor closest to the second sidewall,
wherein the semiconductor device further comprises:
a gate connection line connecting the at least three gate electrodes in the first direction;
a source connection line connecting source regions of the first sub-transistor;
a drain connection line connecting drain regions of the second sub-transistor;
a first common node line connecting drain regions of the first sub-transistor to the common node region; and
a second common node line connecting source regions of the second sub-transistor to the common node region.

20. The semiconductor device of claim 19, wherein a source voltage is applied to the source connection line,
wherein a drain voltage is applied to the drain connection line, and
wherein the source voltage and the drain voltage are not applied to the first common node line and the second common node line.

21. (canceled)
